(19) United States
(12) Patent Application Publication
(10) Pub. No.: US 2012/0136477 A1
(43) Pub. Date: May 31, 2012

(54) Storage Device Transport, Clamping And Testing

(75) Inventors: Brian S. Merrow, Harvard, MA (US); Edward Garcia, Holbrook, MA (US); Evgeny Polyakov, Brookline, MA (US)

(73) Assignee: TERADYNE, INC., North Reading, MA (US)

(21) Appl. No.: 13/264,882

(22) PCT Filed: Apr. 17, 2009
(86) PCT No.: PCT/US2009/040888

§ 371 Date: Jan. 12, 2012

(51) Int. Cl. B65G 49/00; H05K 7/00; G06F 17/00

(52) U.S. Cl. 700/218; 414/222.01; 700/214; 700/213; 361/679.33

(57) ABSTRACT

A storage device transporter (400, 400b, 400c), for transporting a storage device (600) and for mounting a storage device within a test slot (500, 500b), includes a frame (410, 410b, 410c) configured to receive and support a storage device. The frame includes sidewalls (418, 425a, 425b, 429a, 429b) configured to receive a storage device there between and sized to be inserted into a test slot along with a storage device. The frame also includes a clamping mechanism (450) operatively associated with at least one of the sidewalls. The clamping mechanism includes a first engagement element (476, 700, 750) and a first actuator (454, 710, 760) operable to initiate movements of the first engagement element. The first actuator is operable to move the first engagement element into engagement with a test slot after a storage device being supported by the frame is arranged in a test position in a test slot.

### TECHNICAL FIELD

This disclosure relates to the transport, clamping and testing of storage devices.

### BACKGROUND

Disk drive manufacturers typically test manufactured disk drives for compliance with a collection of requirements. Test equipment and techniques exist for testing large numbers of disk drives serially or in parallel. Manufacturers tend to test large numbers of disk drives simultaneously or in batches. Disk drive testing systems typically include one or more tester racks having multiple test slots that receive disk drives for testing. In some cases, the disk drives are placed in carriers which are used for loading and unloading the disk drives to and from the test racks.

The testing environment immediately around the disk drive is closely regulated. Minimum temperature fluctuations in the testing environment are critical for accurate test conditions and for safety of the disk drives. The latest generations of disk drives, which have higher capacities, faster rotational speeds and smaller head clearance, are more sensitive to vibration. Excess vibration can affect the reliability of test results and the integrity of electrical connections. Under test conditions, the drives themselves can propagate vibrations through supporting structures or fixtures to adjacent units. This vibration “cross-talking,” together with external sources of vibration, contributes to bump errors, head slap and non-repetitive run-out (NRRO), which may result in lower yields and increased manufacturing costs. Current disk drive testing systems employ automation and structural support systems that contribute to excess vibrations in the system and/or require large footprints.

In some cases, in order to combat undesirable vibrations, disk drives are clamped to a carrier and/or to a tester rack in such a manner as to inhibit or dampen vibrations.

### SUMMARY

In one aspect, a storage device transporter, for transporting a storage device and for mounting a storage device within a test slot, includes a frame configured to receive and support a storage device. The frame includes a pair of sidewalls configured to receive a storage device therebetween and sized to be inserted into a test slot along with a storage device. The frame also includes a clamping mechanism operatively associated with at least one of the sidewalls. The clamping mechanism includes a first engagement element and a first actuator operable to initiate movements of the first engagement element. The first actuator is operable to move the first engagement element into engagement with a test slot after a storage device being supported by the frame is arranged in a test position in a test slot.

Embodiments can include one or more of the following features. In some embodiments, the first actuator is operable to move the first engagement element into engagement with a storage device being supported by the frame.

In certain embodiments, the first engagement element includes first and second engagement members. In some cases, the first actuator is operable to initiate movements of the first and second engagement members.

In some embodiments, the first actuator is operable to move the first engagement member into engagement with a test slot after a storage device being supported by the frame is arranged in a test position in a test slot. In some cases, the first actuator is operable to move the second engagement member into engagement with a storage device being supported by the frame.

In certain embodiments, the second engagement member includes a dampener. The dampener may include a dampening material selected from thermoplastics and/or rubberthermosets. The dampener may include an isolating or dampening material.

In some embodiments, the first actuator is operable to move the first and second engagement members in substantially opposite directions relative to each other. In some cases, the first actuator is operable to move the first and second engagement members substantially simultaneously.

In certain embodiments, the first engagement element includes a protuberance configured to engage a mating feature in a test slot.

In some embodiments, the first engagement element includes a dampener. The dampener may include a dampening material selected from thermoplastics and/or rubberthermosets.

In certain embodiments, the first engagement element includes a spring clamp. The spring clamp includes a base portion and first and second spring arms. The first and second spring arms each include a proximal end connected to the base portion and a displaceable distal end. In some cases, the actuator is operable to initiate movements of the distal ends of the first and second spring arms.

In some embodiments, the first actuator is pivotable relative to the frame to initiate movements of the first engagement element.

In certain embodiments, the first actuator includes an elongate body extending from a proximal end to a distal end along a first axis. The first actuator is rotatable about the first axis to initiate movements of the first engagement member.

In some embodiments, the first actuator is linearly displaceable relative to the frame to initiate movements of the first engagement member.

In certain embodiments, a first one of the sidewalls defines a first actuator slot, and the first actuator is at least partially disposed within the first actuator slot. In some cases, the first actuator is moveable within the first actuator slot to initiate movements of the first engagement member.

In some embodiments, the clamping mechanism includes a second engagement element, and the first actuator is operable to initiate movements of the second engagement element. In some cases, the first actuator is operable to move the second engagement element into engagement with a test slot after a storage device being supported by the frame is arranged in a test position in the test slot. In some cases, the first actuator is operable to move the second engagement element into engagement with a storage device being supported by the frame.

In certain embodiments, the clamping mechanism includes a second engagement element, and a second actuator operable to initiate movements of the second engagement element. In some cases, the second actuator is operable independently of the first actuator to initiate movements of the second engagement element. In certain cases, the second actuator is operable to move the second engagement element into engagement with a test slot after a storage device being supported by the frame is arranged in a test position in a test slot. In some cases, the second actuator is operable to move the second engagement element into engagement with a storage device being supported by the frame.

In some embodiments. the first actuator defines actuating features for initiating movements of the first engagement element. In some cases, the actuating features include wedges and recesses.

In certain embodiments, the frame includes a base plate connected to the sidewalls. In some cases, the sidewalls and the base plate together define a substantially U-shaped opening for capturing a storage device off of a support.

In another aspect, a storage device test slot includes a housing that defines a test compartment for receiving and supporting a storage device transporter carrying a storage device for testing. The housing also defines an open end that provides access to the test compartment for insertion and removal of storage device transporter carrying a storage device for testing. The test slot also includes a first engagement element mounted to the housing. The first engagement element is configured to engage a storage device carried by a storage device transporter when a storage device transporter is inserted in the test compartment.

Embodiments can include one or more of the following features. In some embodiments, the first engagement element includes a clamping spring.

In certain embodiments, the first engagement element includes a dampener. In some cases, the dampener is configured to engage a storage device carried by a storage device transporter when a storage device transporter is inserted in the test compartment. In certain cases, the dampener includes a dampening material that includes thermoplastics and rubberthermosets.

In a further aspect, a storage device testing system includes automated machinery and a storage device transporter. The storage device transporter includes a frame configured to receive and support a storage device. The automated machinery is configured to releasably engage the frame to control movement of the storage device transporter. The storage device testing system also includes a loading station for storing storage devices to be tested, and a test slot configured to receive and support a storage device transporter carrying a storage device. The automated machinery is operable to remove storage devices from the loading station utilizing the storage device transporter and insert the storage device transporter, having a storage device therein, into the test slot.

Embodiments can include one or more of the following features. In some embodiments, the automated machinery includes a robot. The robot can include, for example, a moveable arm and a manipulator connected to the moveable arm. In some cases, the manipulator is configured to releasably engage the frame to control movement of the storage device transporter. In certain cases, the robot is operable to remove storage devices from the loading station utilizing the storage device transporter and insert the storage device transporter, having a storage device therein, into the test slot.

In certain embodiments. the frame includes a face plate defining an indentation configured to be releasably engageable by the automated machinery.

In some embodiments, the frame includes a clamping mechanism. In some cases, the clamping mechanism includes a first engagement element and a first actuator operable to initiate movements of the first engagement element. In certain examples, the first actuator is operable to move the first engagement element into engagement with the test slot after a storage device being supported by the frame is arranged in a test position in the test slot. In certain cases, the automated machinery is configured to control operation of the clamping mechanism. In some cases, the frame includes a pair of sidewalls configured to receive a storage device therebetween and sized to be inserted into a test slot along with a storage device for testing of the storage device. In some examples, the clamping mechanism is operatively associated with at least one of the sidewalls.

In yet another aspect, a storage device transporter, for transporting a storage device and for mounting a storage device within a test slot, includes a frame having a pair of sidewalls configured to receive a storage device therebetween and sized to be inserted into a test slot along with a storage device. The frame also includes a base plate connecting the sidewalls. The sidewalls and the base plate together define a substantially U-shaped opening for capturing a storage device off of a support.

In a further aspect, a method of testing a storage device includes actuating automated machinery to engage a storage device transporter; capturing a storage device with the storage device transporter; and then actuating the automated machinery to insert the storage device transporter and the captured storage device into a test slot. Capturing the storage device includes moving the storage device transporter into engagement with the storage device using the automated machinery.

Embodiments can include one or more of the following features. In certain embodiments, actuating the automated machinery includes actuating a robotic arm.

In some embodiments, the storage device transporter includes a clamping mechanism operable to clamp the storage device transporter to the test slot, and the method includes actuating the automated machinery to operate the clamping assembly and thereby clamping the storage device transporter to the test slot after the storage device transporter and the captured storage device are inserted into the test slot.

In certain embodiments, capturing the storage device includes actuating the automated machinery to move the storage device transporter into a position underlying the storage device; and actuating the automated machinery to raise the storage device transporter into a position engaging the storage device.

In another aspect, a method of testing a storage device includes actuating automated machinery to insert a storage device transporter carrying a storage device into a test slot, and actuating the automated machinery to operate a clamping mechanism and thereby clamping the storage device transporter to the test slot after the storage device transporter and the captured storage device are inserted into the test slot.

Embodiments can include one or more of the following features. In some embodiments, actuating automated machinery includes actuating a robotic arm.

In certain embodiments, the method may include actuating the automated machinery to engage the clamping assembly and thereby clamping the storage device transporter to the captured storage device.

In a further aspect, a test slot assembly includes a test slot and a storage device transporter. The test slot includes a housing that defines a test compartment, and an open end, which provides access to the test compartment. The storage device transporter includes a frame configured to receive and support a storage device. The frame includes a pair of sidewalls configured to receive a storage device therebetween and sized to be inserted into the test compartment along with a storage device. The frame also includes a clamping mechanism operatively associated with at least one of the sidewalls. The clamping mechanism includes a first engagement element and a first actuator operable to initiate movements of the first engagement element. The first actuator is operable to move the first engagement element into engagement with the housing after a storage device being supported by the frame is arranged in a test position in the test compartment.

Embodiments can include one or more of the following features. In some embodiments, the first engagement element includes first and second engagement members, and the first actuator is operable to initiate movements of the first and second engagement members. In some examples, the first actuator is operable to move the first engagement member into engagement with the test slot after a storage device being supported by the frame is arranged in a test position in the test compartment, and the first actuator is operable to move the second engagement member into engagement with a storage device being supported by the frame. In some cases, the second engagement member includes a dampener. In some implementations, the first actuator is operable to move the first and second engagement members in substantially opposite directions relative to each other. In some examples, the first actuator is operable to move the first and second engagement members substantially simultaneously.

In certain embodiments, the housing includes a pair of upstanding walls configured to receive the sidewalls of the frame therebetween. In some cases, a first one of the upstanding walls includes an engagement feature, and the first engagement element includes a protuberance configured to engage the engagement feature. In some examples, the first actuator is operable to move the protuberance into engagement with the engagement feature after the sidewalls are inserted into the test compartment.

In still another aspect, a test slot assembly includes a storage device transporter and a housing. The storage device transporter includes a frame configured to receive and support a storage device. The frame includes a pair of sidewalls configured to receive a storage device therebetween. A first one of the sidewalls defines a pass-through aperture. The housing defines a test compartment for receiving and supporting the storage device transporter, and an open end providing access to the test compartment for insertion and removal of the storage device transporter. The test slot assembly also includes a first engagement element mounted to the housing. The first engagement element is configured to extend through the pass-through aperture to engage a storage device carried by the storage device transporter when the storage device transporter is inserted in the test compartment.

In a further aspect, a storage device testing system includes automated machinery and

a storage device transporter. The storage device transporter includes a frame configured to receive and support a storage device. The storage device transporter also includes a clamping mechanism. The clamping mechanism includes a first engagement element, and a first actuator operable to initiate movements of the first engagement element. The automated machinery is configured to control operation of the clamping mechanism.

Embodiments can include one or more of the following features. In some embodiments, the automated machinery is configured to releasably engage the frame to control movement of the storage device transporter

In certain embodiments, the automated machinery includes a robot. The robot may include a moveable arm and a manipulator connected to the moveable arm. In some cases, for example, the manipulator is configured to releasably engage the frame to control movement of the storage device transporter. In some examples, the manipulator is operable to control operation of the clamping mechanism.

In some embodiments, the frame includes a face plate defining an indentation configured to be releasably engageable by the automated machinery.

In another aspect, a method of transporting storage devices for testing includes actuating automated machinery and thereby moving a storage device transporter carrying a first storage device between a first test slot and a loading station; and actuating the automated machinery to operate a clamping mechanism such that the storage device transporter is clamped to the first storage device during movement between the first test slot and the loading station.

Embodiments can include one or more of the following features. In some embodiments. In certain embodiments, moving the storage device transporter between the first test slot and the loading station includes moving the storage device transporter carrying the first storage device from the loading station to the first test slot.

In some embodiments, moving the storage device transporter between the first test slot and the loading station includes moving the storage device transporter carrying the first storage device from the first test slot to the loading station.

In certain embodiments, actuating the automated machinery to operate the clamping mechanism includes clamping the storage device transporter to the first storage device prior to moving the storage device transporter between the first test slot and the loading station.

In some embodiments, actuating the automated machinery to operate the clamping mechanism includes clamping the storage device transporter to the first storage device as the storage device transporter is being moved between the first test slot and the loading station.

In certain embodiments, the method includes actuating the automated machinery to operate the clamping mechanism and thereby unclamping the storage device transporter from the first storage device, and then actuating the automated machinery to insert the storage device transporter and the first storage device into the first test slot. The method may also include actuating the automated machinery to operate the clamping mechanism and thereby clamping the storage device transporter to the first test slot after the storage device transporter and the first storage device are inserted into the first test slot.

In some embodiments, the method includes actuating the automated machinery to operate the clamping mechanism and thereby unclamping the storage device transporter from the first test slot; and then actuating the automated machinery to remove the storage device transporter from the first test slot. In some cases, the method may also include actuating the automated machinery to operate the clamping mechanism and thereby unclamping the storage device transporter from the first storage device prior to removing the storage device transporter from the first test slot.

In certain embodiments, the method includes actuating the automated machinery to operate the clamping mechanism and thereby unclamping the storage device transporter from a second test slot; and then actuating the automated machinery and thereby removing the storage device transporter from the second test slot. In some cases, the method also includes capturing the first storage device from the loading station with the storage device transporter after removing the storage device transporter from the second test slot. Capturing the first storage device includes moving the storage device transporter into engagement with the first storage device using the automated machinery. In some examples, the method also includes actuating the automated machinery to operate the clamping mechanism and thereby unclamping the storage device transporter from a second storage device. Removing the storage device transporter from the second test slot comprises removing the storage device transporter carrying the second storage device from the second test slot. The method may also include actuating the automated machinery and thereby moving the storage device transporter carrying the second storage device between the second test slot and the loading station, and actuating the automated machinery to operate the clamping mechanism such that the storage device transporter is clamped to the second storage device during movements between the second test slot and the loading station. In some cases, the method includes actuating the automated machinery to insert the storage device transporter and the second storage device into a storage device receptacle at the loading station.

In some embodiments, the method includes actuating the automated machinery to insert the storage device transporter into the first test slot; and then actuating the automated machinery to operate the clamping mechanism and thereby clamping the storage device transporter to the first test slot after the storage device transporter is inserted into the first test slot.

In a further aspect, a method of transporting storage devices for testing includes actuating automated machinery and thereby moving a storage device transporter carrying a first storage device between a first test slot and a second test slot; and actuating the automated machinery to operate a clamping mechanism such that the storage device transporter is clamped to the first storage device during movement between the first test slot and the second test slot.

Embodiments can include one or more of the following features. In some embodiments. In certain embodiments, actuating the automated machinery to operate the clamping mechanism includes clamping the storage device transporter to the first storage device prior to moving the storage device transporter between the first test slot and the second test slot.

In some embodiments, actuating the automated machinery to operate the clamping mechanism includes clamping the storage device transporter to the first storage device as the storage device transporter is being moved between the first test slot and the second test slot.

In certain embodiments, moving the storage device transporter between the first test slot and the second test slot includes moving the storage device transporter carrying the first storage device from the first test slot towards the second test slot. In some cases, the method also includes actuating the automated machinery to operate the clamping mechanism and thereby unclamping the storage device transporter from the first test slot; and then actuating the automated machinery to remove the storage device transporter from the first test slot. The method may also include actuating the automated machinery to operate the clamping mechanism and thereby unclamping the storage device transporter from the first storage device prior to removing the storage device transporter from the first test slot.

In some embodiments, the method includes actuating the automated machinery to operate the clamping mechanism and thereby unclamping the storage device transporter from the first storage device, and then actuating the automated machinery to insert the storage device transporter and the first storage device into the second test slot. In some examples, the method also includes actuating the automated machinery to operate the clamping mechanism and thereby clamping the storage device transporter to the second test slot after the storage device transporter and the first storage device are inserted into the second test slot.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a perspective view of a storage device testing system.

FIG. 2A is perspective view of a test rack.

FIG. 2B is a detailed perspective view of a slot bank from the test rack of FIG. 2A.

FIG. 3 is a perspective view of a test slot assembly.

FIGS. 4A and 4B are schematic views of self-test and functional test circuitry.

FIG. 5 is a perspective view of a load station.

FIG. 6 is a perspective view of a tote and storage device.

FIG. 7 is a schematic view of a storage device testing system.

FIG. 8 is an exploded perspective view of a storage device transporter.

FIG. 9 is a perspective view of a clamping mechanism.

FIGS. 10A and 10B are perspective views of a spring clamp.

FIG. 11 is a perspective view of an actuator.

FIGS. 12A and 12B are perspective views of a storage device transporter frame.

FIGS. 13A-13D illustrate the assembly of a storage device transporter.

FIG. 14 is a perspective view of a storage device transporter.

FIG. 15A is a sectioned plan view a storage device transporter with spring clamps in an engaged position.

FIG. 15B is a detailed view of one of the spring clamps of FIG. 15A.

FIG. 16A is a sectioned plan view of a storage device transporter with spring clamps in a disengaged position.

FIG. 16B is a detailed view of one of the spring clamps of FIG. 16A.

FIGS. 17A and 17B are perspective and plan views of a storage device transporter supporting a storage device.

FIG. 18 is a plan view of a storage device transported clamped to a storage device.

FIG. 19A is a perspective view of a test slot.

FIG. 19B is a perspective view of a test compartment from the test slot of FIG. 19A.

FIG. 20A is a plan view showing a storage device transporter, supporting a storage device, inserted in a test slot.

FIG. 20B is a detailed view of a spring clamp from FIG. 20A.

FIG. 21 is a schematic illustration of a storage device transporter capturing a storage device from a tote.

FIG. 22 is a perspective view of a test slot assembly.

FIG. 23A is a perspective view of a test slot.

FIG. 23B is a perspective view of a test compartment from the test slot of FIG. 23A.

FIG. 24 is a perspective view of a clamping spring.

FIGS. 25A and 25B are perspective views of a storage device transporter.

FIG. 25C is a perspective view of the storage device transporter of FIGS. 25A and 25B supporting a storage device.

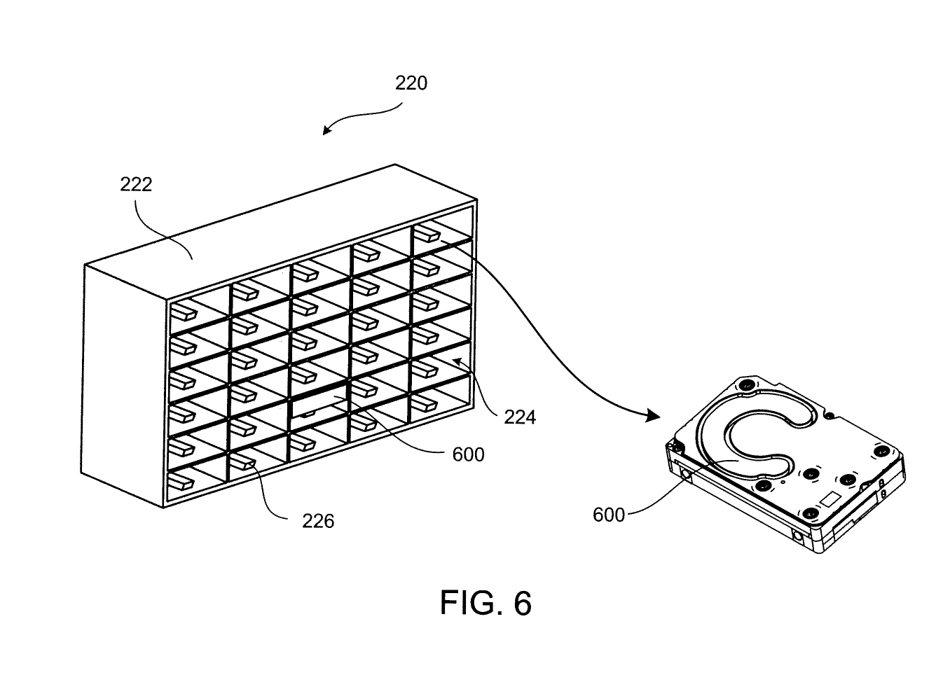

FIGS. 6A is a perspective view showing a storage device transporter inserted in a test slot.

FIG. 26B is plan view showing a storage device transporter, supporting a storage device, inserted in a test slot.

FIGS. 27A and 27B are perspective views of a storage device transporter.

FIG. 28 is a perspective view of a spring clamp.

FIG. 29 is a perspective view of a clamping assembly.

FIG. 30A illustrates the clamping assembly of FIG. 29 in an engaged position.

FIG. 30B illustrates a clamping assembly of FIG. 29 in a disengaged position.

FIG. 31 is a perspective view of the storage device transporter of FIGS. 27A and 27B supporting a storage device.

FIG. 32 is plan view showing a storage device transporter, supporting a storage device, inserted in a test slot.

FIGS. 33A and 33B are perspective views of a storage device transporter.

FIG. 34 is a perspective view of a spring clamp.

FIG. 35 is a perspective view of a clamping assembly.

FIG. 36A is a side view of a storage device transporter showing an actuator in an engaged position.

FIG. 36B illustrates the clamping assembly of FIG. 35 in an engaged position.

FIG. 37A is a side view of a storage device transporter showing an actuator in a disengaged position.

FIG. 37B illustrates the clamping assembly of FIG. 35 in a disengaged position.

FIG. 38 is a perspective view of the storage device transporter of FIGS. 33A and 33B supporting a storage device.

Like reference symbols in the various drawings indicate like elements.

### DETAILED DESCRIPTION

### System Overview

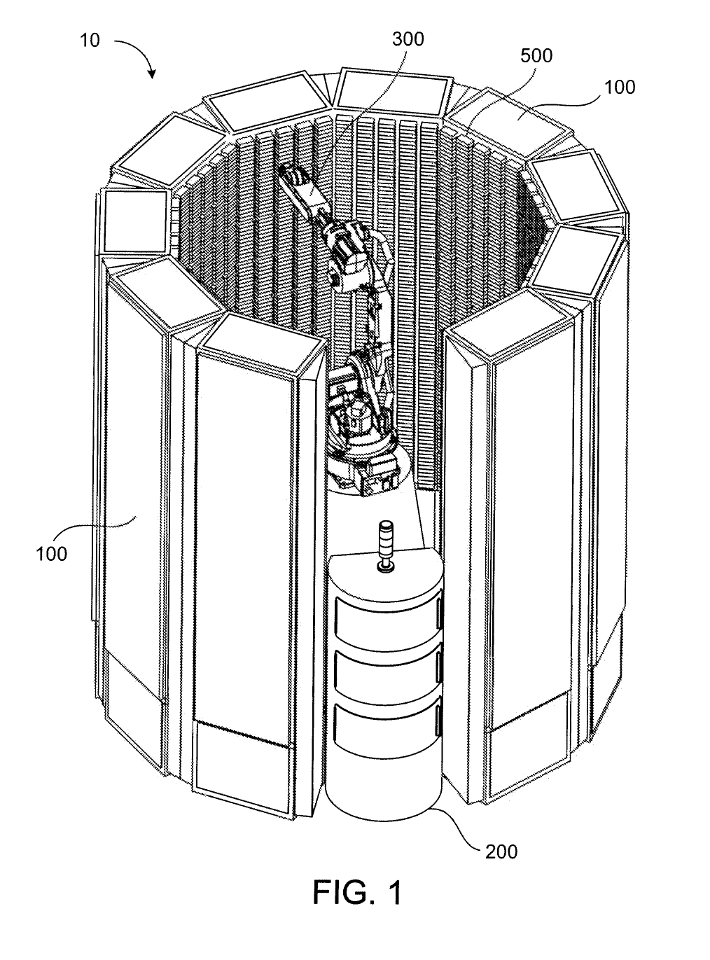

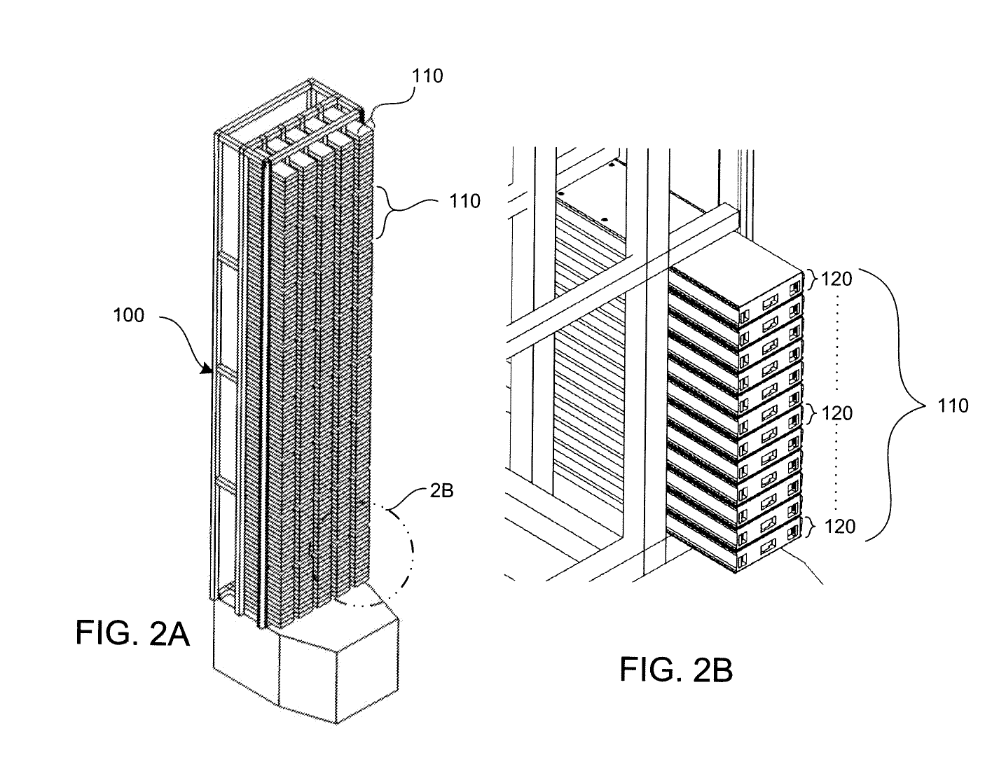

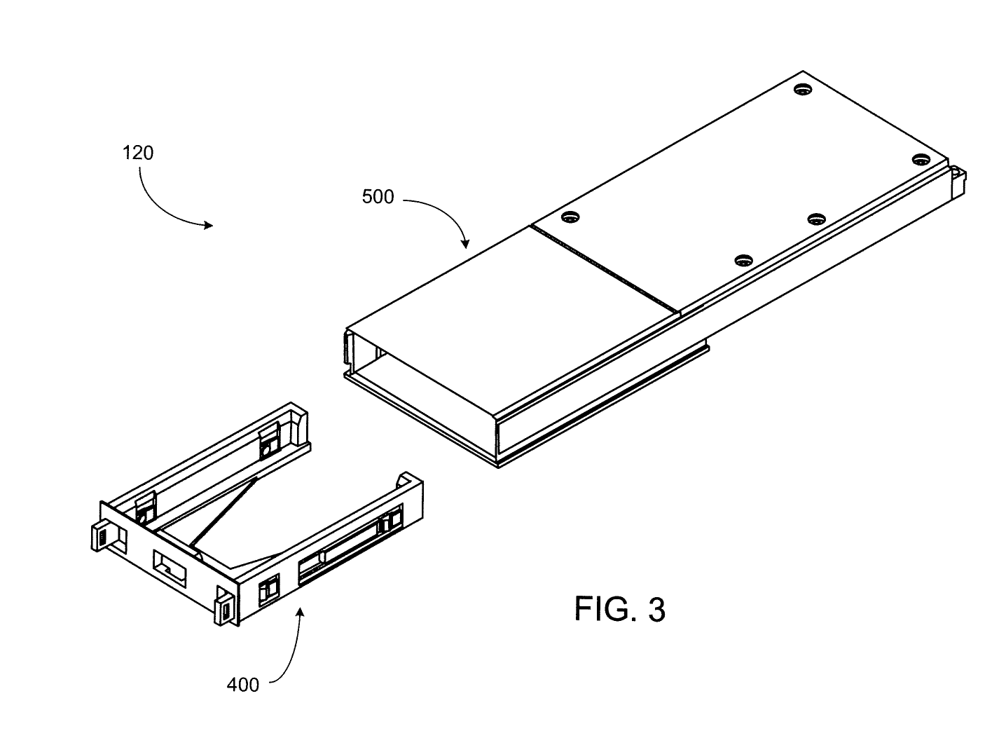

As shown in FIG. 1, a storage device testing system 10 includes a plurality of test racks 100 (e.g., 10 test racks shown), a loading station 200, and a robot 300. As shown in FIGS. 2A and 2B, each test rack 100 includes a plurality of slot banks 110, and each slot bank 110 holds a plurality of test slot assemblies 120. As shown in FIG. 3, each test slot assembly 120 includes a storage device transporter 400 and a test slot 500. The storage device transporter 400 is used for capturing storage devices 600 (FIG. 6) (e.g., from the loading station) and for transporting the storage device 600 to one of the test slots 500 for testing. A storage device, as used herein, includes disk drives, solid state drives, memory devices, and any device that requires asynchronous testing for validation. A disk drive is generally a non-volatile storage device which stores digitally encoded data on rapidly rotating platters with magnetic surfaces. A solid-state drive (SSD) is a data storage device that uses solid-state memory to store persistent data. An SSD using SRAM or DRAM (instead of flash memory) is often called a RAM-drive. The term solid-state generally distinguishes solid-state electronics from electromechanical devices.

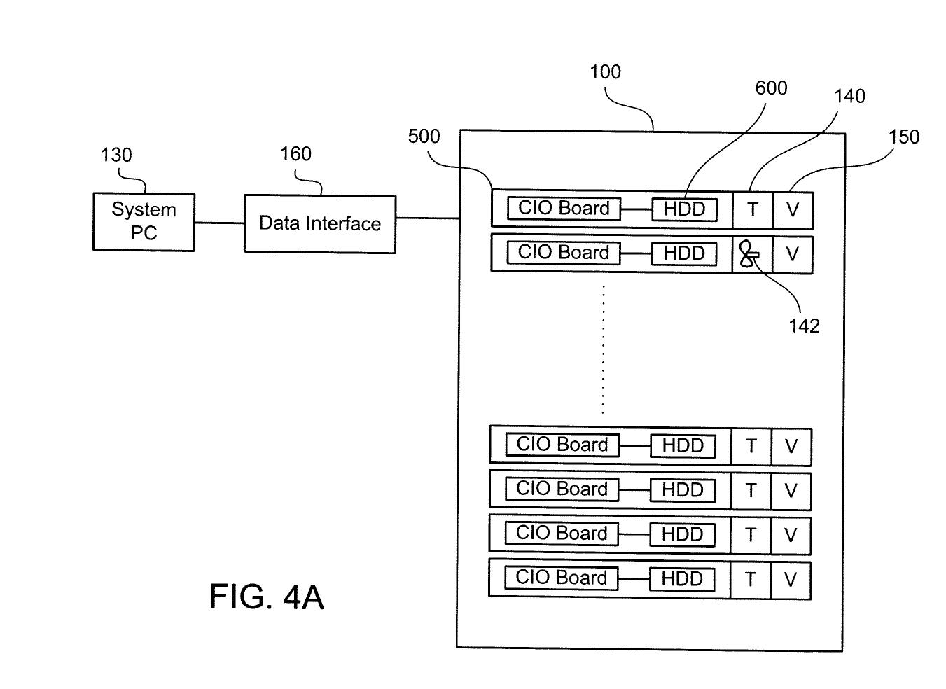

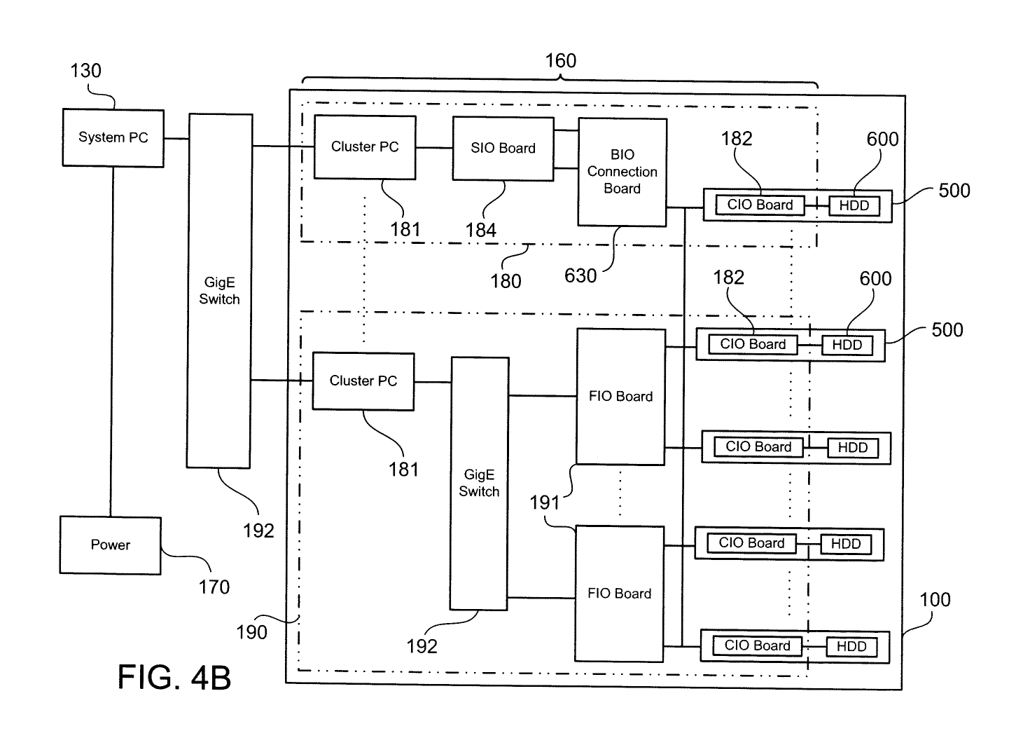

Referring to FIG. 4A, in some implementations, the storage device testing system 10 also includes at least one computer 130 in communication with the test slots 500. The computer 130 may be configured to provide inventory control of the storage devices 600 and/or an automation interface to control the storage device testing system 10. A temperature control system 140 controls the temperature of each test slot 500. The temperature control system 140 can include an air mover (e.g., a fan 142) operable to circulate air through the test slot 500. A vibration control system 150 controls the vibration of each test slot 500. A data interface 160 is in communication with each test slot 500. The data interface 160 is configured to communicate with a disk dive 600 within the test slot 500.

As shown in FIG. 4B, a power system 170 supplies power to the storage device testing system 10. The power system 170 may monitor and/or regulate power to the storage device 600 in the test slot 500. In the example illustrated in FIG. 4B, each rack 100 includes at least one self-testing system 180 in communication with at least one test slot 500. The self-testing system 180 includes a cluster controller 181, a connection interface circuit 182 in electrical communication with a storage device 600 within the test slot 500, and a block interface circuit 183 in electrical communication with the connection interface circuit 182. The cluster controller 181, in some examples, is configured to run one or more testing programs with a capacity of approximately 120 self-tests and/or 60 functionality test of storage devices 600. The connection interface circuit 182 and the block interface circuit 183 are configured to self-test. However, the self-testing system 180 may include a self-test circuit 184 configured to execute and control a self-testing routine on one or more components of the storage device testing system 10. The cluster controller 181 may communicate with the self-test circuit 184 via Ethernet (e.g. Gigabit Ethernet), which may communicate with the block interface circuit 183 and onto the connection interface circuit 182 and storage device 600 via universal asynchronous receiver/transmitter (UART) serial links. A UART is usually an individual (or part of an) integrated circuit used for serial communications over a computer or peripheral device serial port. The block interface circuit 183 is configured to control power and temperature of the test slot 500, and may control up to six test slots 500 and/or storage devices 600.

Each rack 100, in some examples, includes at least one functional testing system 190 in communication with at least one test slot 500. The functional testing system 190 includes a cluster controller 181 and at least one functional interface circuit 191 in electrical communication with the cluster controller (e.g., cluster PC 181). A connection interface circuit 182 is in electrical communication with a storage device 600 within the test slot 500 and the functional interface circuit 182. The functional interface circuit 182 is configured to communicate a functional test routine to the storage device 600. The functional testing system 190 may include a communication switch 192 (e.g. Gigabit Ethernet) to provide electrical communication between the cluster controller 181 and the one or more functional interface circuits 182. The computer 130, communication switch 192, cluster controller 181, and functional interface circuit 191 may communicate on an Ethernet network. However, other forms of communication may be used. The functional interface circuit 191 may communicate to the connection interface circuit 182 via Parallel AT Attachment (a hard disk interface also known as IDE, ATA, ATAPI, UDMA and PATA), SATA, or SAS (Serial Attached SCSI).

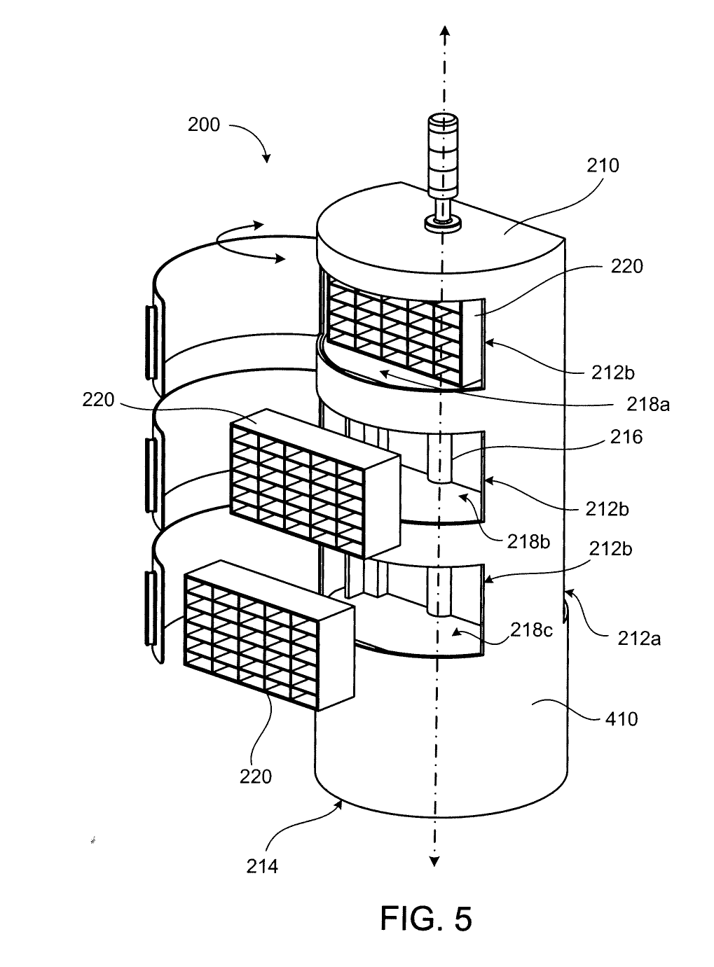

As shown in FIG. 5, the load station 200 includes a load station body 210 that defines first and second sets of tote receptacles 212a, 212b disposed on opposite sides of the load station body 210. The load station 200 also includes a load station base 214 and a spindle 216 that extends substantially normal to and upwardly from the load station base 214. First, second, and third body portions 218a, 218b, 218c are rotatably secured to the spindle 216. Each of the first, second, and third body portions 218a, 218b, 218c is independently rotatable relative to the others.

The load station 200 also includes totes 220 configured to be removably mounted within the tote receptacles 212a, 212b. As shown in FIG. 6, the totes 220 include a tote body 222 which defines a plurality of storage device receptacles 224 (e.g., 30 shown) configured to each house a storage device 600. Each of the storage device receptacles 224 includes a storage device support 226 configured to support a central portion of a received storage device 600 to allow manipulation of the storage device 600 along non-central portions. Referring again to FIG. 5, the totes 200 can be loaded through the first tote receptacles 212a and then rotated into alignment with the second tote receptacles 212b via the first, second, and third body portions 218a-c for servicing by the robot 300.

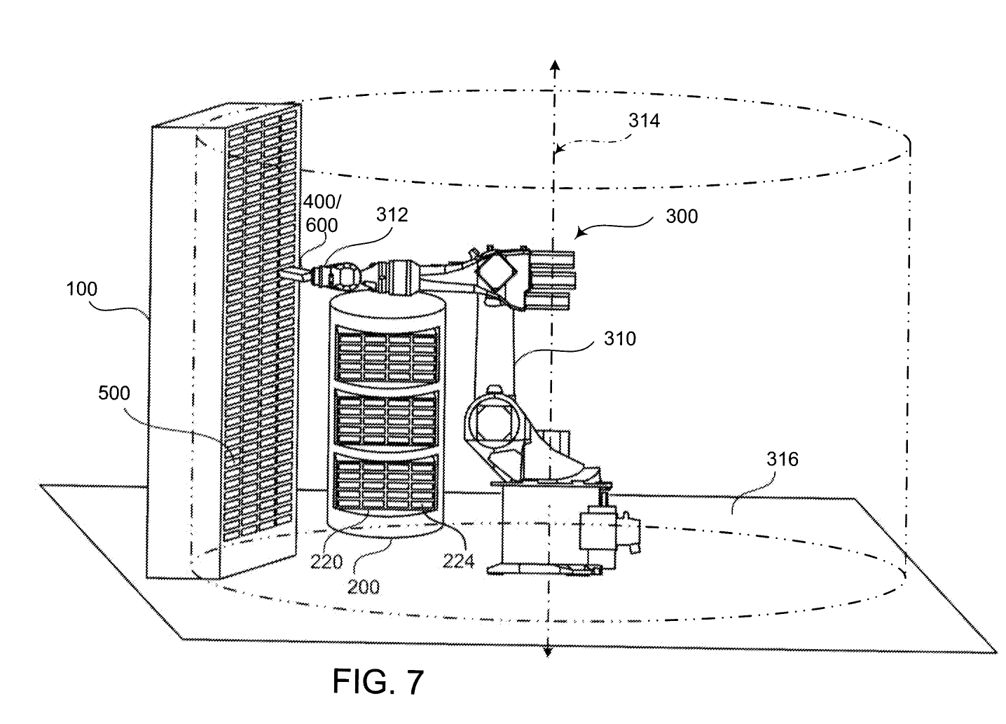

As shown in FIG. 7, the robot 300 includes a robotic arm 310 and a manipulator 312 disposed at a distal end of the robotic arm 310. The robotic arm 310 defines a first axis 314 substantially normal to a floor surface 316 and is operable to rotate through a predetermined arc about and extends substantially radially from the first axis 314. The robotic arm 310 is configured to independently service each test slot 500 by transferring storage devices 600 between the load station 200 and one of the test racks 100. In particular, the robotic arm 310 is configured to remove a storage device transporter 400 from one of the test slots 500 with the manipulator 312, then pick up a storage device 600 from one the storage device receptacles 224 at the load station 200 with the storage device transporter 400, and then return the storage device transporter 400, with a storage device 600 therein, to the test slot 500 for testing of the storage device 600. After testing, the robotic arm 310 retrieves the storage device transporter 400, along with the supported storage device 600, from the test slot 500 and returns it to one of the storage device receptacles 224 at the load station 200.

### Storage Device Transporter

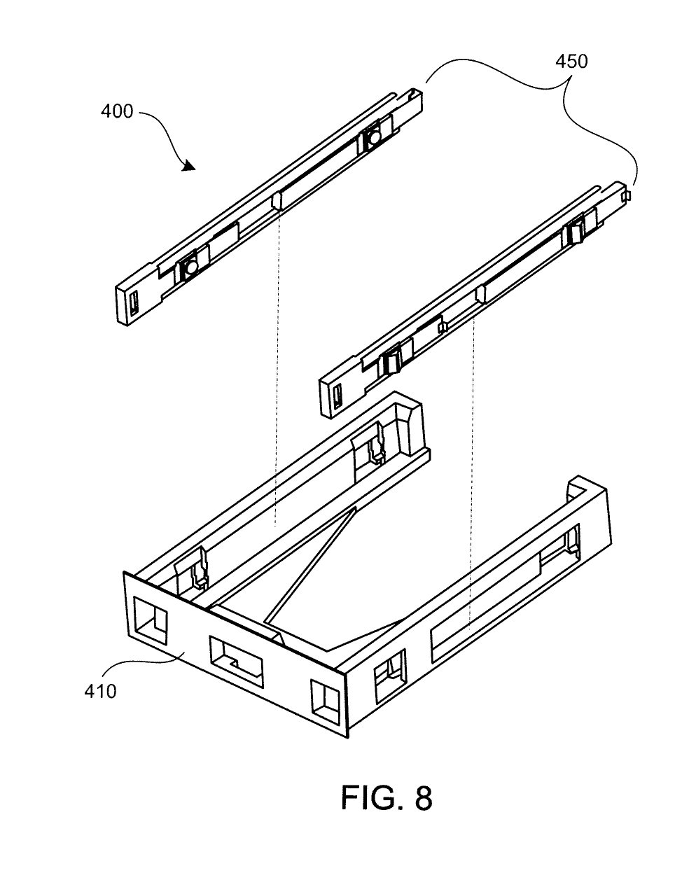

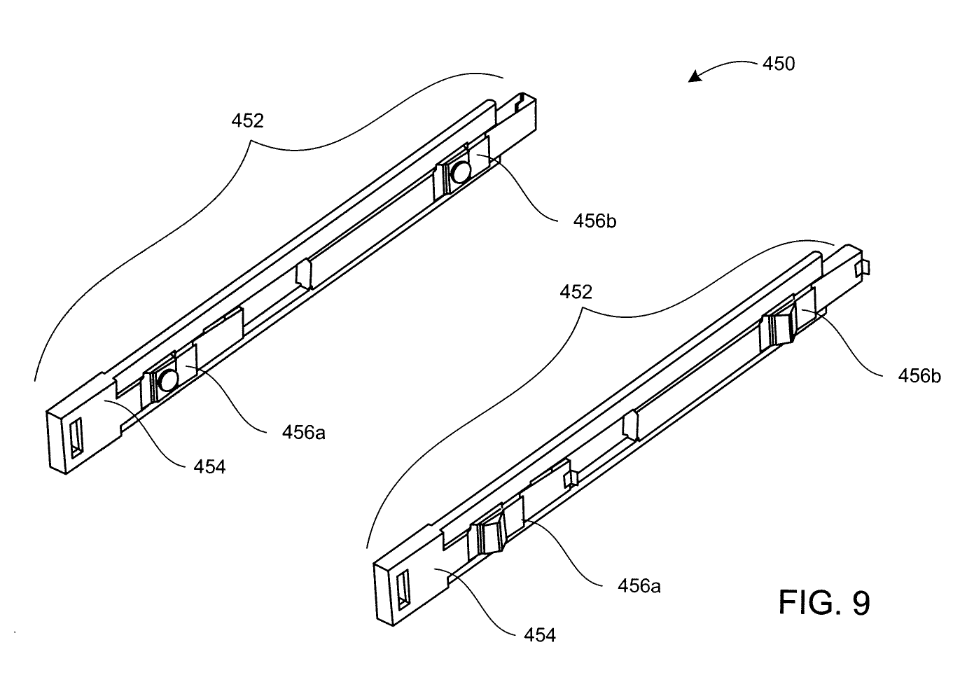

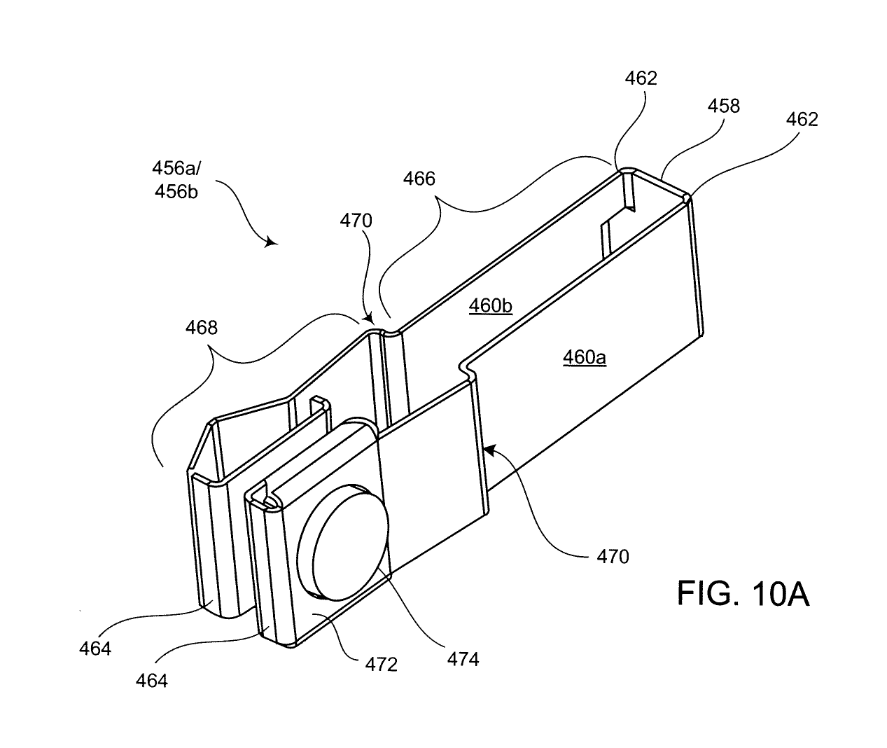

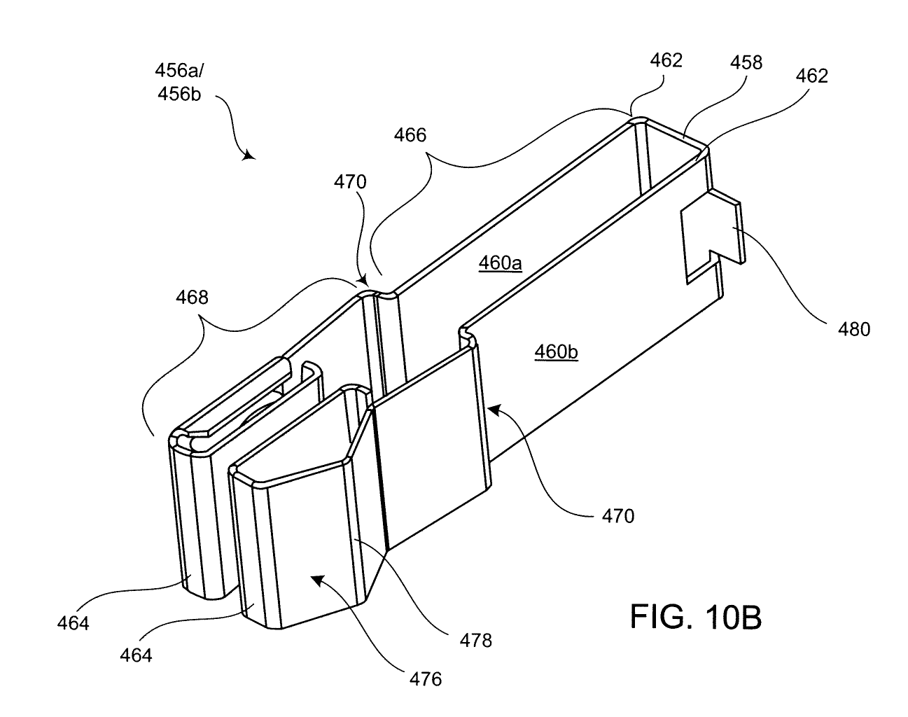

As shown in FIG. 8, the storage device transporter 400 includes a frame 410 and a clamping mechanism 450. As shown in FIG. 9, the clamping mechanism includes a pair of clamping assemblies 452 each including an actuator 454 and a pair of spring clamps (i.e., proximal and distal spring clamps 456a, 456b). As shown in FIGS. 10A and 10B, the spring clamps 456a, 456b include a base portion 458 and first and second spring arms 460a, 460b each having a proximal end 462 connected to the base portion 458 and a displaceable distal end 464. The spring clamps 456a, 456b can be formed from sheet metal, e.g., stainless steel. Between their proximal and distal ends 462, 464 the spring arms 460a, 460b define a narrow region 466, a broad region 468 and a pair of edges 470 therebetween. As shown in FIG. 10A, the first spring arm 460a includes a first engagement member 472 having a dampener 474. The dampener 474 can be formed from, e.g., thermoplastics, thermosets, etc. As shown in FIG. 10B, the second spring arm 460b includes a second engagement member 476 which defines a protuberance 478. Each of the spring clamps 456a, 456b also include a mounting tab 480 that extends outwardly from the base portion 458. As discussed in greater detail below, following assembly, the spring clamps 456a, 456b are mounted to the frame 410 and are operatively associated with the actuators 454 (e.g., for clamping a hard drive 600 within the frame and/or for clamping the frame within one of the test slots 500).

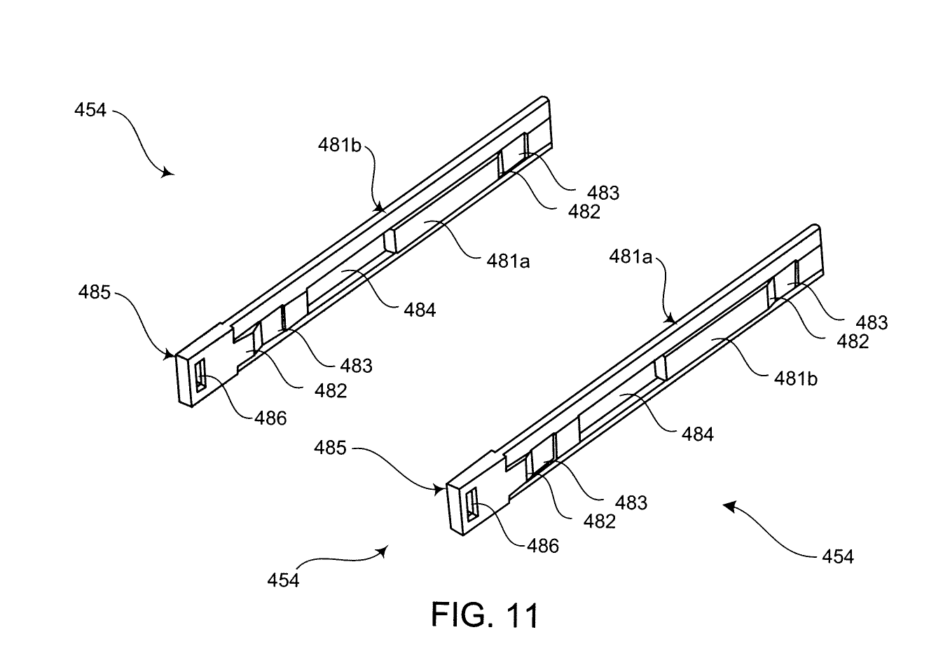

As shown in FIG. 11, each of the actuators 454 includes inner and outer surfaces 481a, 481b which define actuating features. The actuating features include wedges 482 and recesses 483. The actuators 454 also define openings 484 which extend between the inner and outer surfaces 481a, 481b. At their proximal ends 485, the actuators 454 include actuator sockets 486 which are configured to be engageable with the manipulator 312 for controlling movement of the actuators 454 relative to the frame 410.

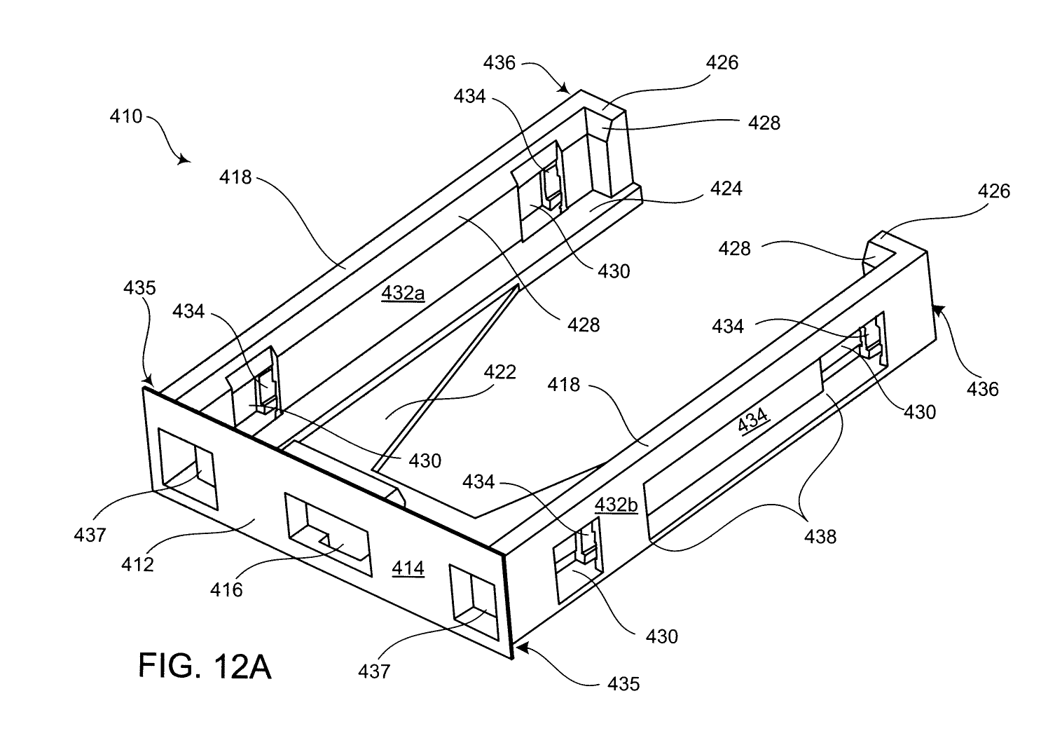

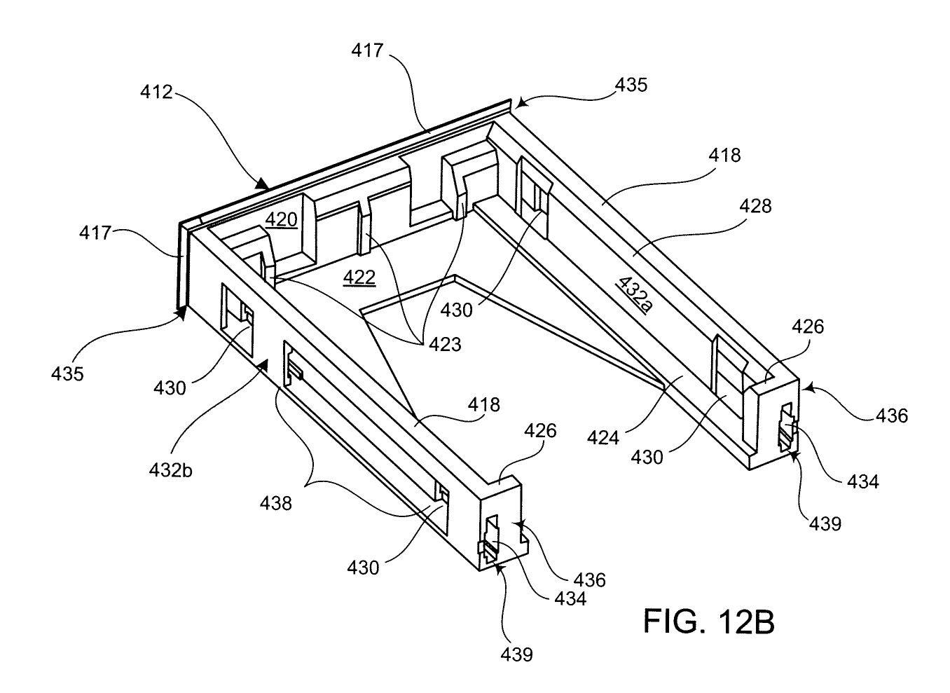

As shown in FIGS. 12A and 12B, the frame 410 includes a face plate 412. Along a first surface 414, the face plate 412 defines an indentation 416. The indentation 416 can be releaseably engaged by the manipulator 312 of the robotic arm 310, which allows the robotic arm 310 to grab and move the storage device transporter 400. The face plate 412 also includes beveled edges 417. When the storage device transporter 400 is inserted into one of the test slots 500, the beveled edges 417 of the face plate 412 abut complimentary beveled edges 515 of the test slot 500 to form a seal, which, as described below, helps to inhibit the flow of air into and out of the test slot 500.

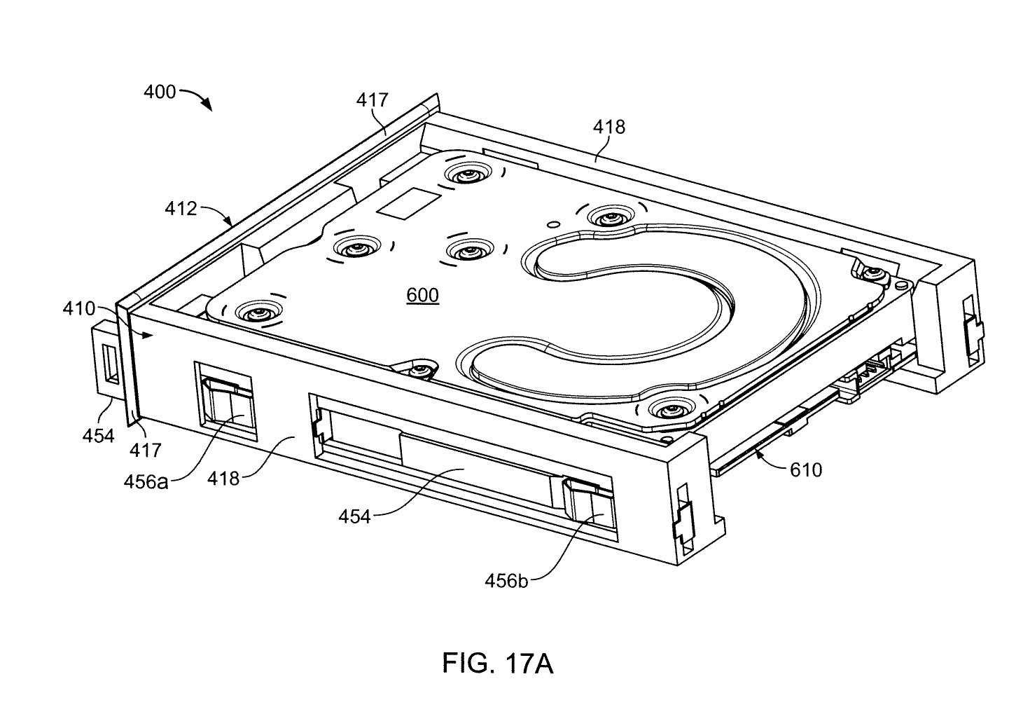

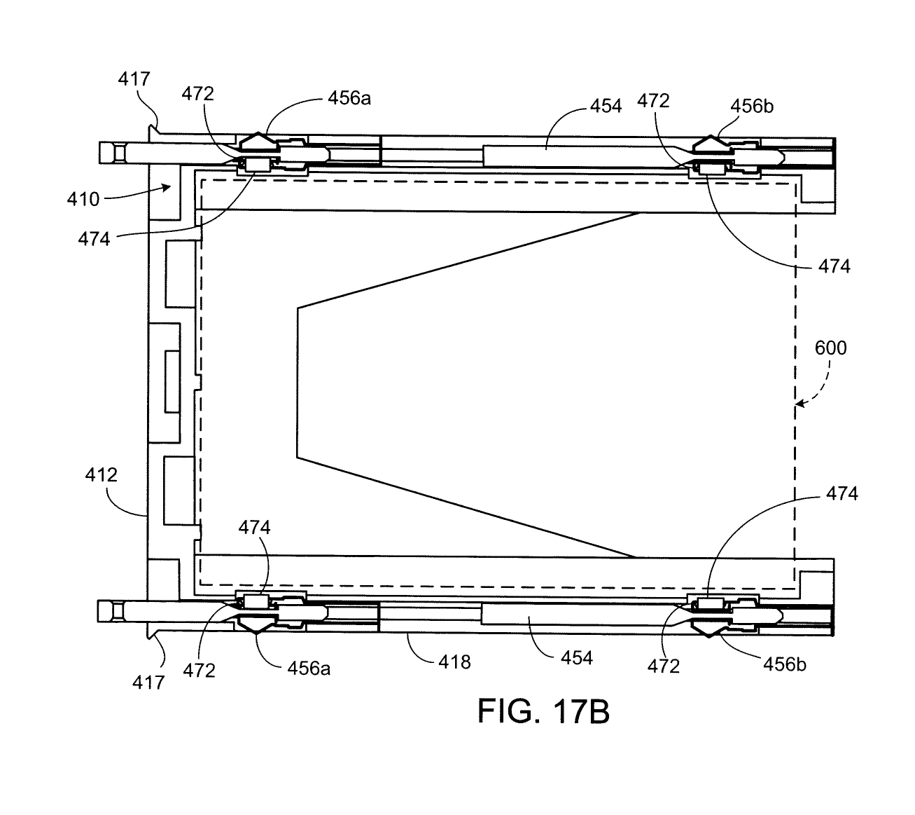

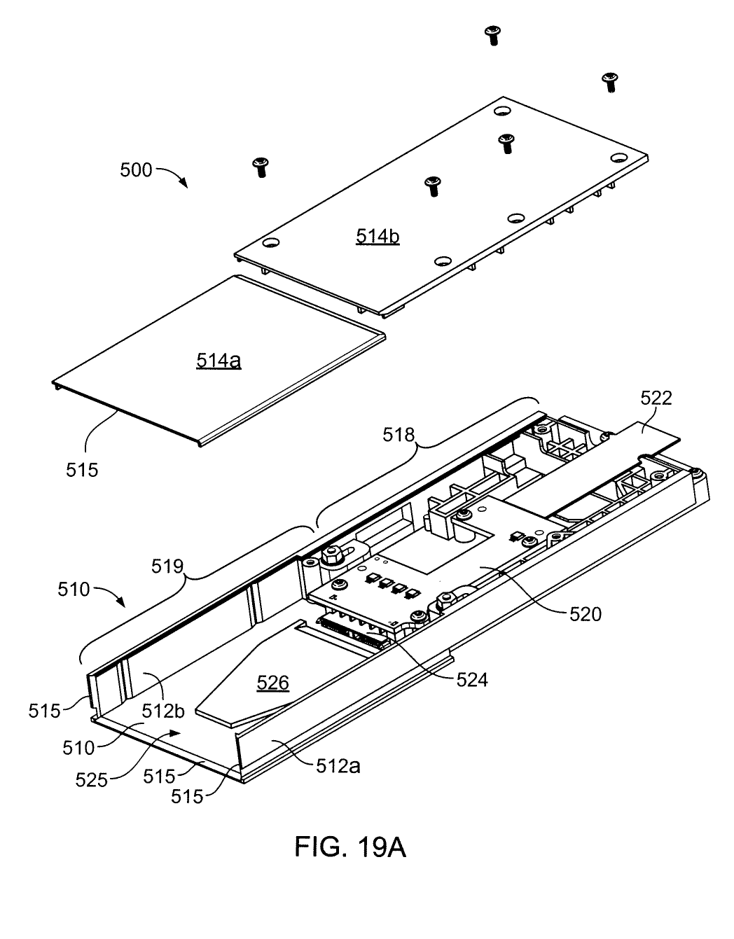

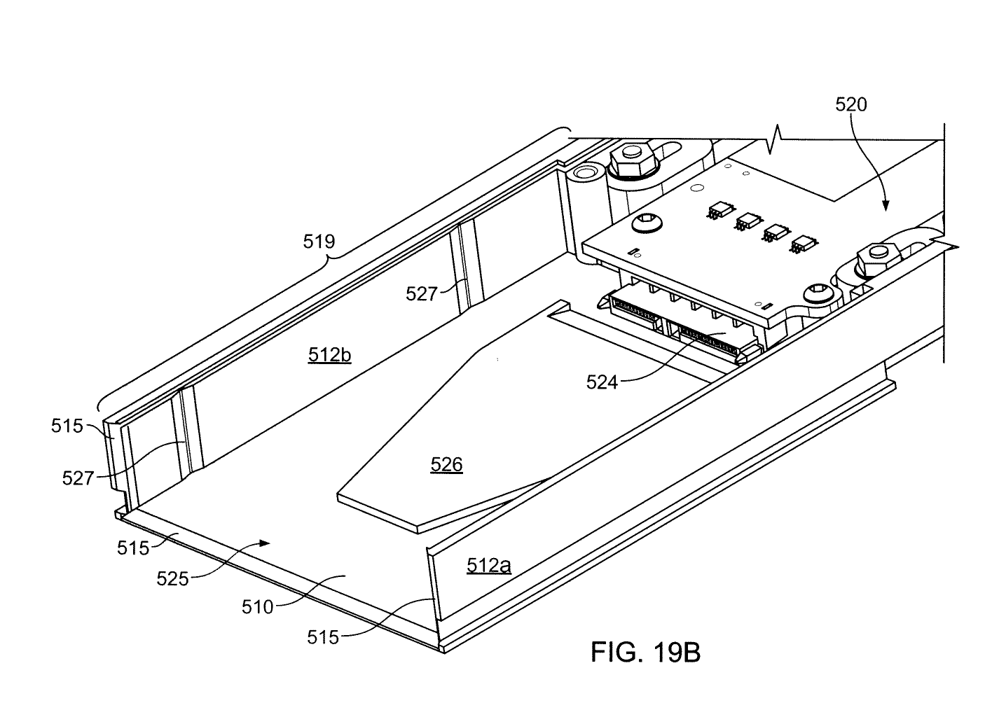

Referring still to FIGS. 12A and 12B, the frame 410 also includes a pair of sidewalls 418, which extend outwardly from a second surface 420 of the face plate 412, and a base plate 422 that extends between and connects the sidewalls 418. The sidewalls 418 and the base plate 422 together define a substantially U-shaped opening, which, as described in greater detail below, allows the storage device transporter 400 to be used to capture a storage device 600 off of the storage device supports 226 in the totes 220. As shown in FIG. 12B, along the second surface 420, the face plate 412 defines projections 423, which can aid in applying force to the storage device 600 to help ensure a mating connection between the storage device connector 610 (FIG. 17A)and the test slot connector 524 (FIGS. 19A & 19B).

The sidewalls 418 are spaced to receive a storage device 600 (shown in hidden lines) therebetween, and define surfaces 424 for supporting a storage device 600. The sidewalls 418 also define back hooks 426, which can be useful for extracting the storage device 600 from a test slot 500 (e.g., for separating a connector on the storage device from a mating connector in the test slot 500). The sidewalls 418 also define lead-ins 428 (e.g., chamfered edges), which can aid in centering a storage device 600 in the frame 410.

The sidewalls 418 each define a pair of pass-through apertures 430, which extend between inner and outer surfaces 432a, 432b of the sidewalls 418. Following assembly, a corresponding one of the spring clamps 456a, 456b is associated with each of the pass-through apertures 430. The sidewalls 418 also define actuator slots 434 which extend from a proximal end 435 to a distal end 436 of each sidewall 418. The face plate 412 defines a pair of apertures 437 which extend between the first and second surfaces 414, 420 thereof, and which allow access to the actuator slots 434. The sidewalls 418 also define partial through-holes 438 which provide access to the actuator slots 434 from the outer surfaces 432b of the sidewalls 418.

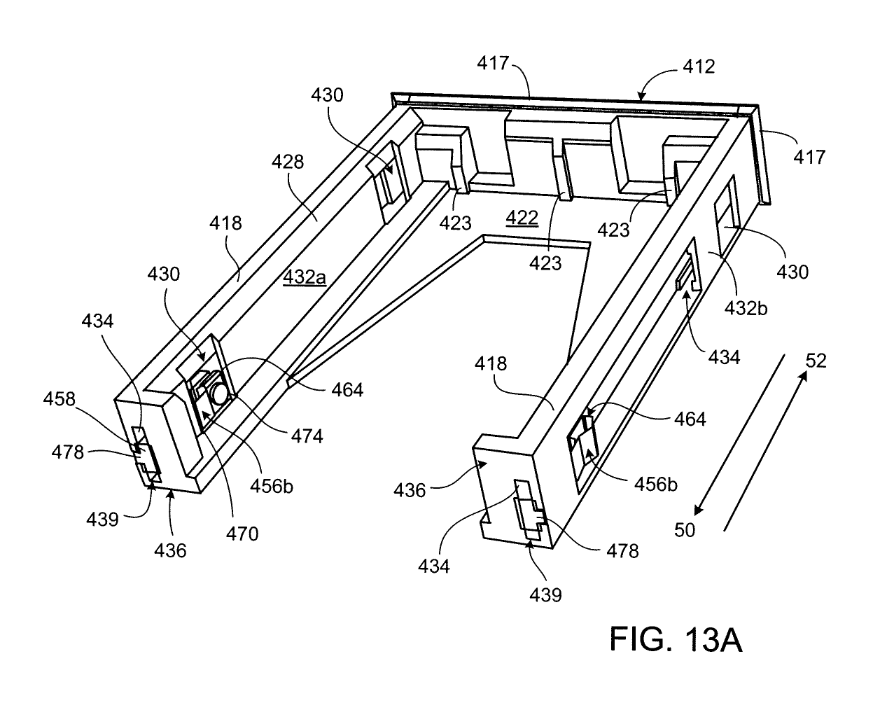

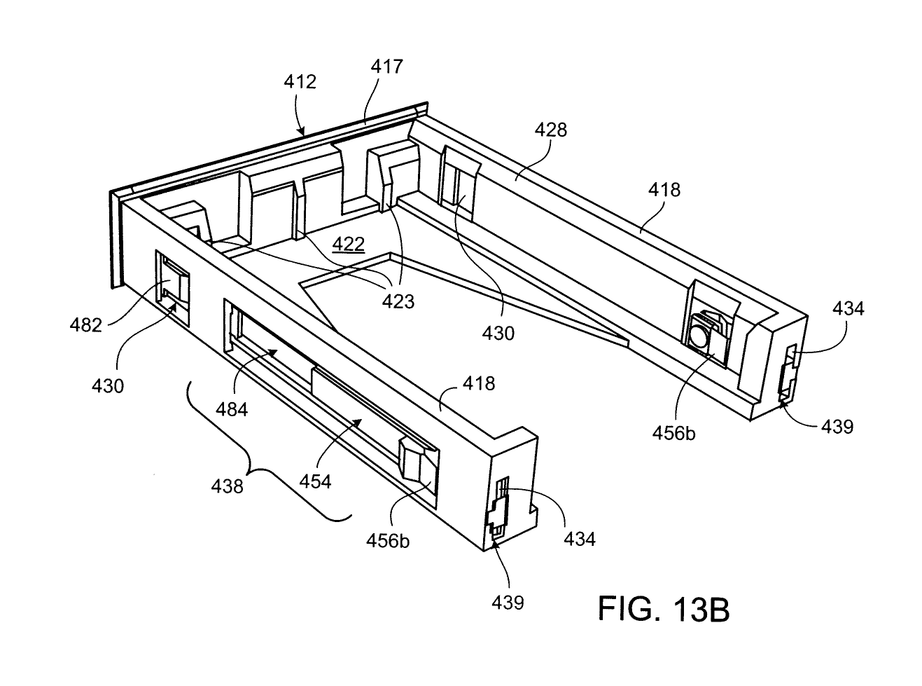

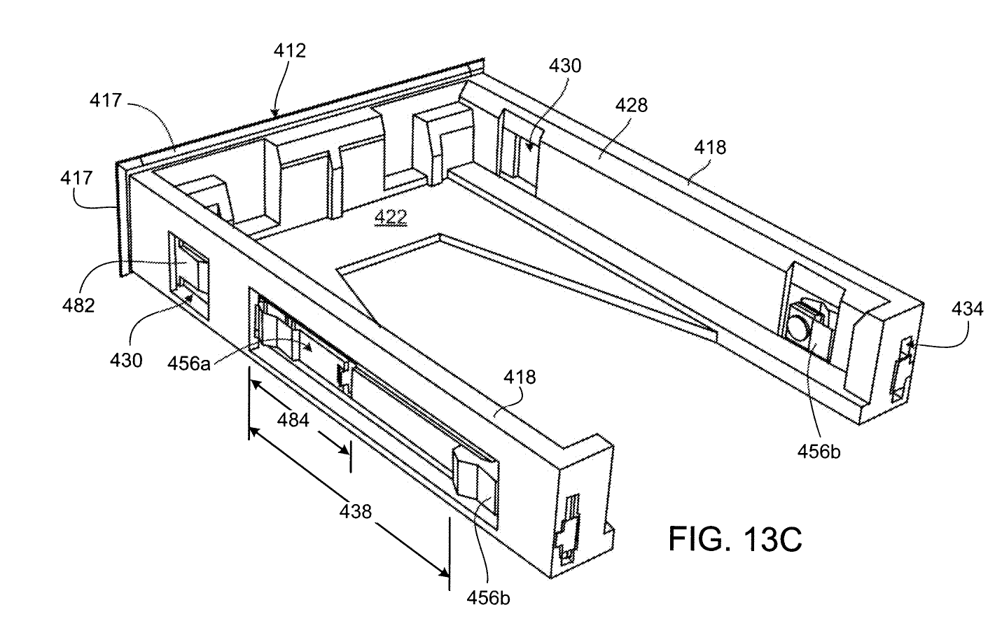

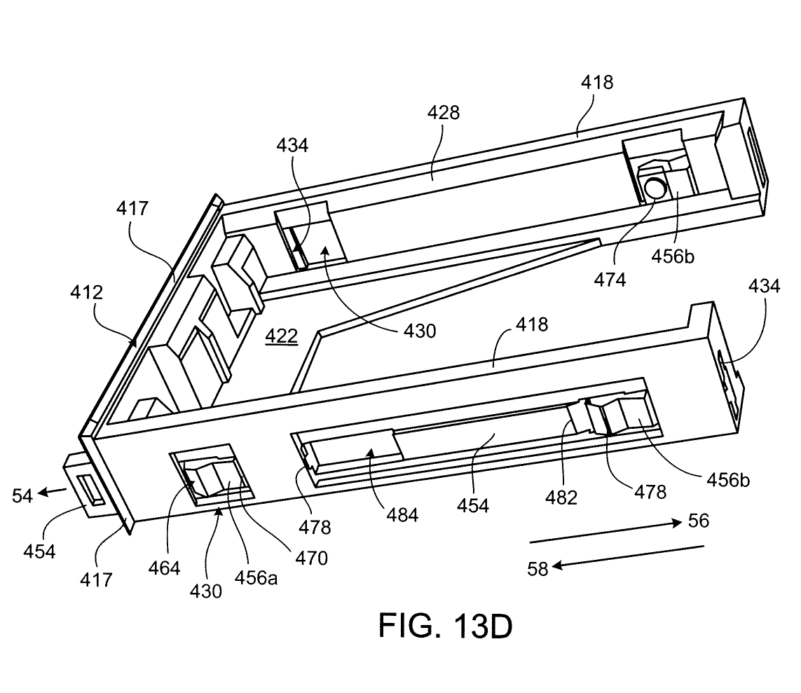

FIGS. 13A-D, illustrate the assembly of the clamping mechanism 450 with the frame 410. As shown in FIG. 13a, the distal spring clamps 456b are inserted into the actuator slots 434 through openings 439 in the distal ends 436 of the sidewalls 418. During insertion, the displaceable distal ends 464 of the distal spring clamps 456b are compressed by the inner surfaces of the actuator slot 434 such that the broad regions 468 of the distal spring clamps 456b fit within the corresponding actuator slots 434. The distal spring clamps 456b are then advanced into the actuator slot 434 until the edges 470 reach the distal pass-through apertures 430, at which point the distal ends 464 of the distal spring clamps 456b extend outwardly toward their rest position with the edges 470 abutting surfaces of the pass-though apertures 430. In this position, the edges 470 inhibit reward movement (indicated by arrow 50) of the distal spring clamps 456b and the tabs 480 abut the distal ends 436 of the sidewalls 418 to inhibit forward movement (indicated by arrow 52) of the distal spring clamps 456b. In this manner, the distal spring clamps 456b are substantially fixed against further linear movement within the actuator slots 434.

Next, as shown in FIG. 13B, a first one of the actuators 454 is inserted into a first one of the actuator slots 434 through the face plate 412 and is advanced into the slot 434 until the opening 484 in the actuator 454 is aligned with the partial through-hole 438 in the associated sidewall 418. With the actuator 454 in this position, a first one of the proximal spring clamps 456a can be aligned in the opening 484 through the partial through-hole 438, as shown in FIG. 13C. Referring to FIG. 13D, with the proximal spring clamp 456a so aligned, the actuator 454 can be retracted (as indicated by arrow 54) to push the proximal spring clamp 456a forward. During forward movement, the displaceable distal ends 464 of the proximal spring clamp 456a are compressed by the inner surfaces of the actuator slot 434 such that the broad regions 468 of the spring clamp 456a fit within the corresponding actuator slot 434. The proximal spring clamp 456a is advanced, via movement of the actuator 454, into the actuator slot 434 until the edges 470 reach the proximal pass-through apertures 430, at which point the distal ends 464 of the proximal spring clamp 456a extend outwardly toward their rest position with the edges 470 abutting surfaces of the pass-though aperture 430. In this position, the edges 470 inhibit reward movement (indicated by arrow 56) of the proximal spring clamps 456a and the tabs 480 abut the surface forming the partial through-hole 438 to inhibit forward movement (indicated by arrow 58) of the proximal spring clamp 456a. In this manner, the proximal spring clamp 456a is substantially fixed against further linear movement within the actuator slots 434. Assembly of the other proximal spring clamp 456a in on the other sidewall 418 is performed in the same manner.

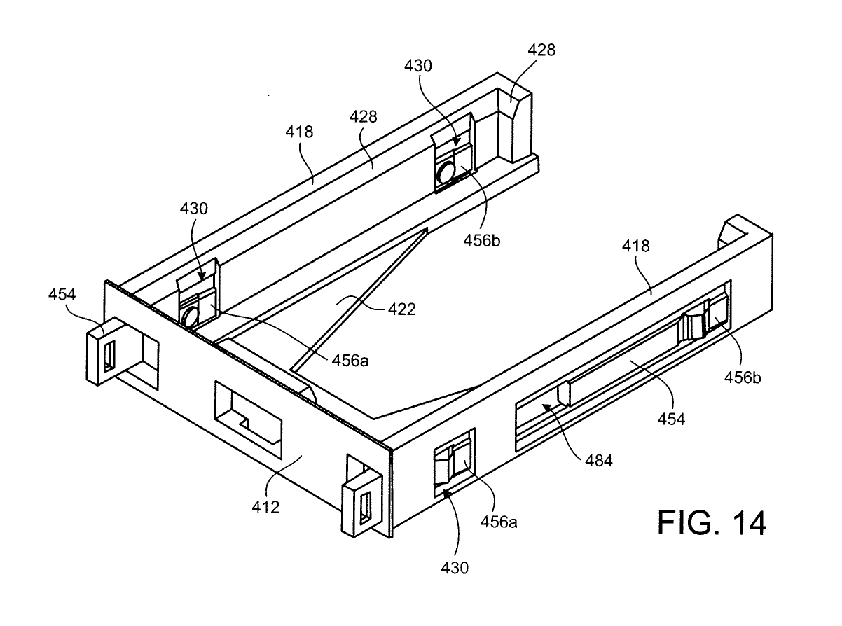

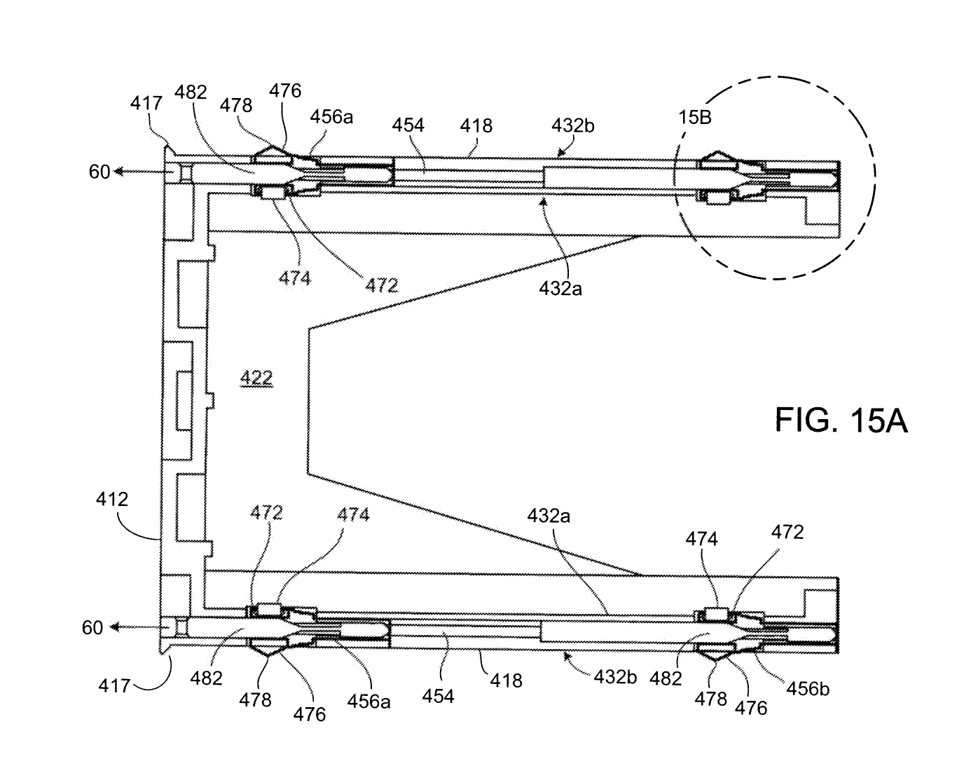

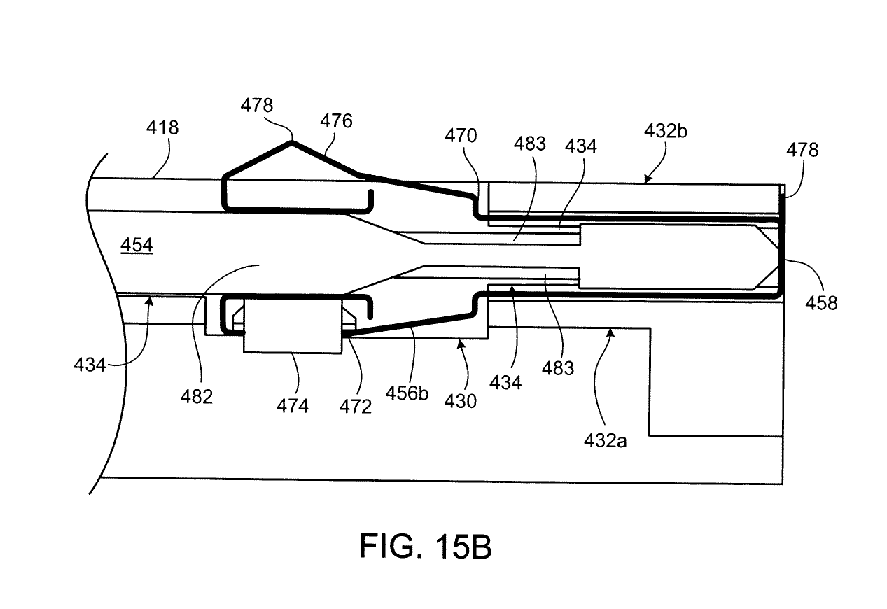

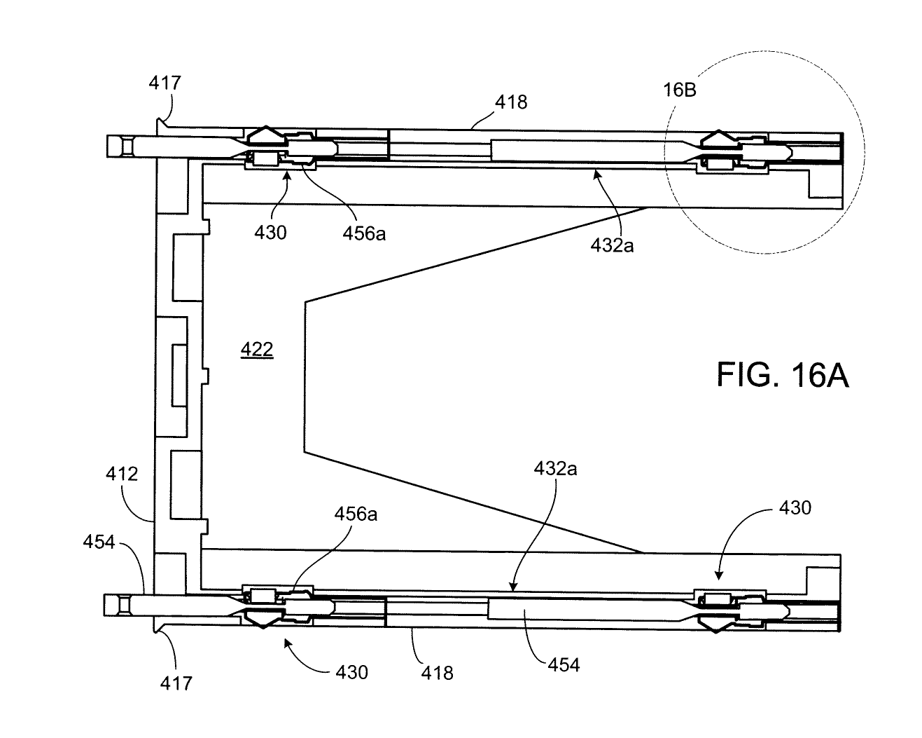

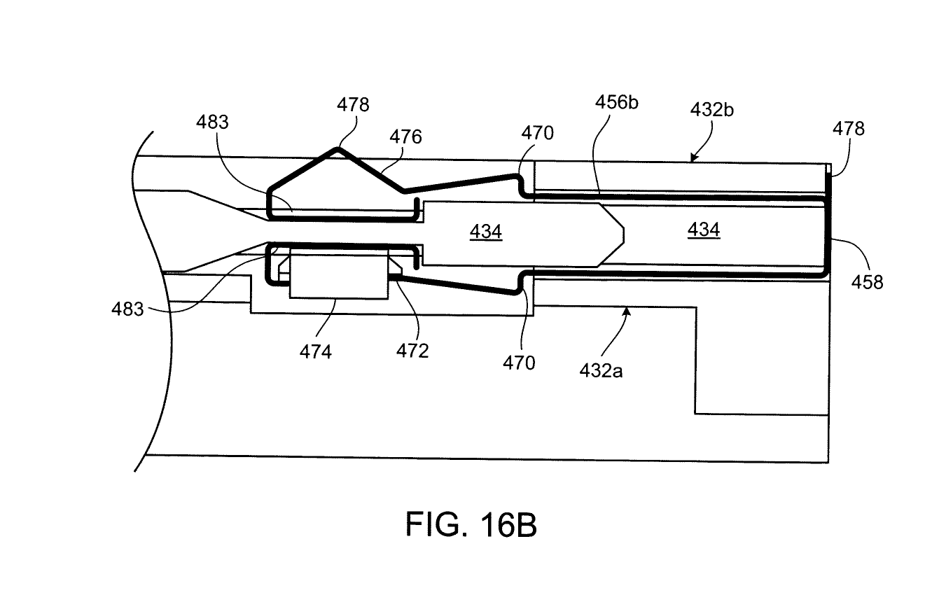

Referring to FIG. 14, following assembly, the actuators 454 are each independently slidable within the corresponding actuator slot 434 and are moveable relative to the sidewalls 418 between an engaged and a release position. As shown in FIGS. 15A and 15B, in the engaged position, the wedges 482 of the actuators 454 engage the spring clamps 456a, 456b to cause the first and second engagement members 472, 476 of the spring arms 460a, 460b to extend outwardly from the inner and outer surfaces 432a, 432b of the sidewalls 418. The first and second engagement members 472, 476 of the spring clamps 456a, 456b can also be retracted by pulling the actuators 454 outwardly from the first surface 414 of the face plate 414 (as indicated by arrow 60). As shown in FIGS. 16A and 16B, when the actuators 454 have been retracted to the release position, the engagement members 472, 476 are allowed to retract to a rest position within the recesses 483 of the actuators 454.

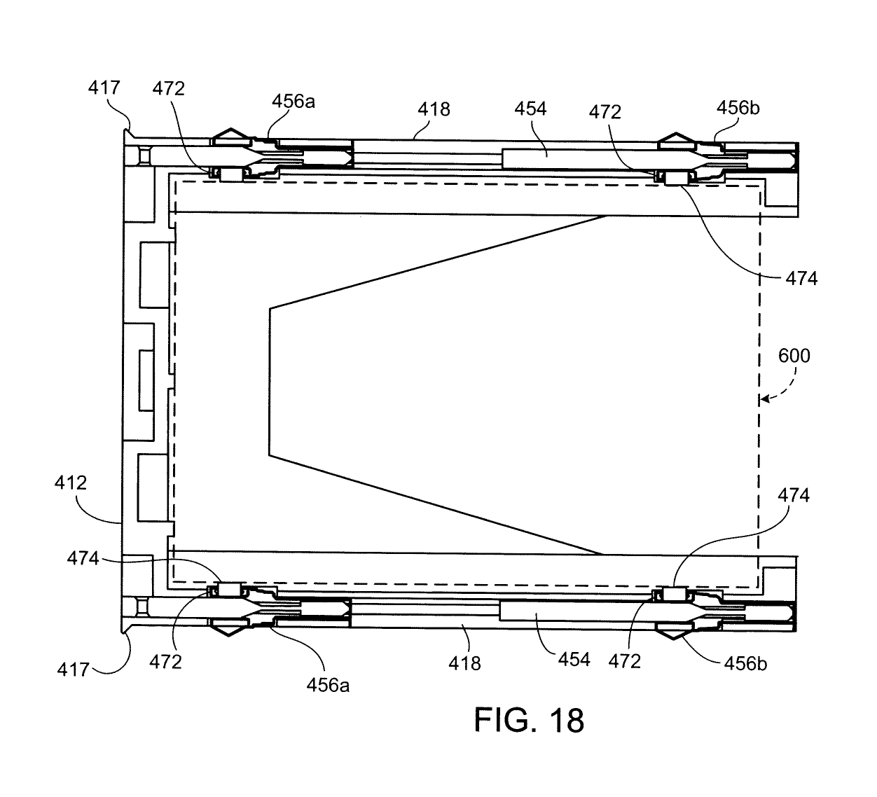

As shown in FIGS. 17A and 17B, when the actuators 454 are in the release position, with the spring clamps 456a, 456b retracted, a storage device 600 (shown hidden in FIG. 17B) can be inserted into the frame 410 between the sidewalls 418. With a storage device 600 inserted in the frame 410, the actuators 454 can be moved towards the engaged position to displace the first engagement members 472 into contact with the storage device 600 to clamp the storage device 600 against movement relative to the frame 410, as shown in FIG. 18. When engaged with the storage device 600, the dampeners 474 can help to inhibit the transfer of vibrations between storage device transporter 400 and the storage device 600. The dampeners 474 can also help to limit metal to metal contact between the spring clamps 456a, 456b and the storage device 600.

### Test Slot

As shown in FIG. 19A, the test slot 500 includes a base 510, upstanding walls 512a, 512b and first and second covers 514a, 514b. The test slot 500 includes a rear portion 518 and a front portion 519. The rear portion 518 houses a connection interface board 520, which carries the connection interface circuit 182 (FIGS. 4A and 4B). The connection interface board 520 includes a ribbon cable 522, which provides for electrical communication between the connection interface circuit 182 (FIGS. 4A and 4B) and the test circuitry (e.g., self test system 180 and/or functional test system 190) in the associated test rack 100. The connection interface board 520 also includes a test slot connector 524, which provides for electrical communication between the connection interface circuit 182 and a storage device in the test slot 500. The front portion 519 of the test slot 500 defines a test compartment 526 for receiving and supporting one of the storage device transporters 400. The base 510, upstanding walls 512a, 512b, and the first cover 514a together define a first open end 525, which provides access to the test compartment 526 (e.g., for inserting and removing the storage device transporter 400), and the beveled edges 515, which abut the face plate 412 of a storage device transporter 400 inserted in the test slot 500 to provide a seal that inhibits the flow of air into and out of the test slot 500 via the first open end 525.

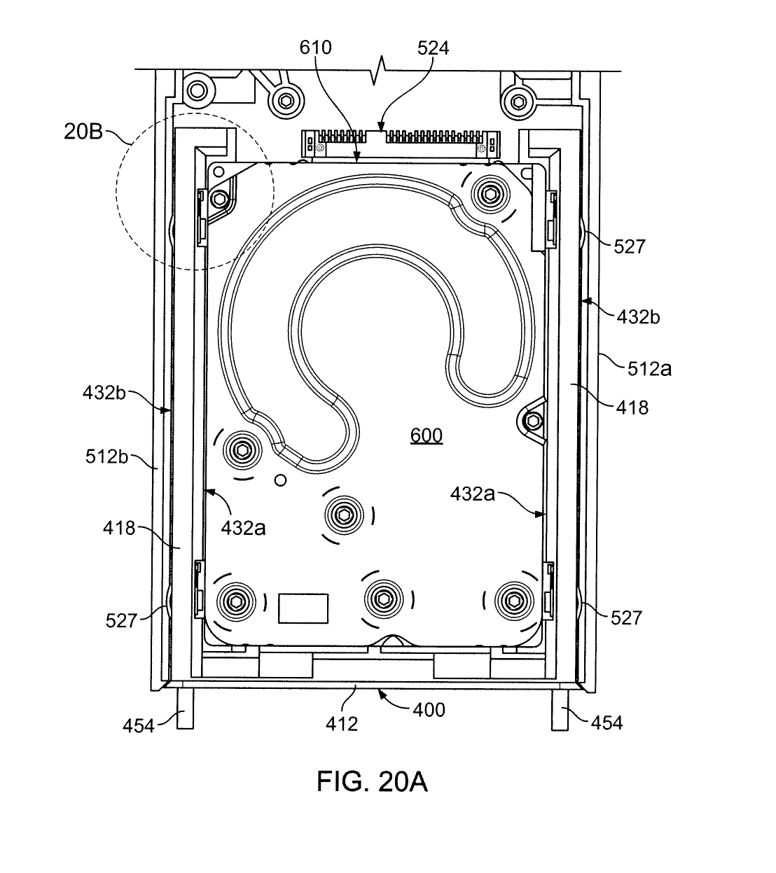

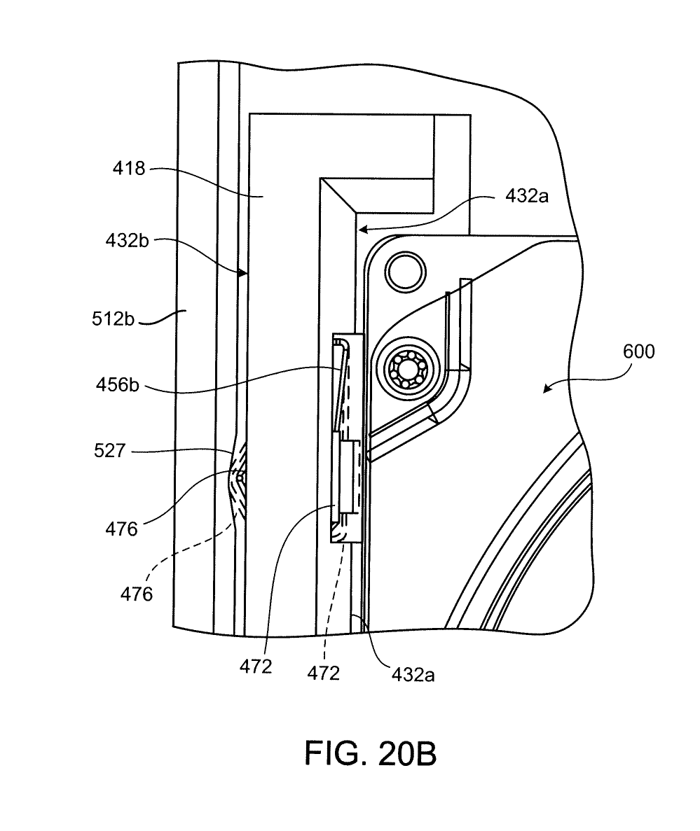

As shown in FIG. 19B, in the region of the test compartment 526, the upstanding walls 512a, 512b define engagement features 527, which provide mating surfaces for the spring clamps 456a, 456b of the storage device transporter 400 allowing the storage device transporter 400 to be clamped within the test slot 500. For example, with a storage device 600 in the storage device transporter 400 and with the actuators 454 in the release position, the storage device transporter 400 can be inserted into a test slot 500 until a connector 610 on the storage device 600 mates with the test slot connector 524, as shown in FIG. 20A. With the storage device transporter 400 in a fully inserted position within the test slot 500 (i.e., with the storage device connector 610 mated with the test slot connector 524), the actuators 454 can be moved towards the engaged position to displace the first and second engagement members 472, 476 of the spring clamps 456a, 456b to extend outwardly from the inner and outer surfaces 432a, 432b of the sidewalls 418. As shown in hidden lines in FIG. 20B, in the engaged position, the second engagement members 476 extend outwardly from the outer surfaces 432b of sidewalls 418 and engage the engagement features 527 in the test slot 500 to clamp the storage device transporter 400 against movement relative to the test slot 500. At the same time, the first engagement members 472 extend outwardly from the inner surfaces 432a of the sidewalls 418 and engage the storage device 600 to clamp the storage device 600 against movement relative to the storage device transporter 400. The storage devices 600 can be sensitive to vibrations. Fitting multiple storage devices 600 in a single test rack 100 and running the storage devices 600 (e.g., during testing), as well as the insertion and removal of storage devices 600 from the various test slots 500 in the test rack 100 can be sources of undesirable vibration. In some cases, for example, one of the storage devices 600 may be operating under test within one of the test slots 500, while others are being removed and inserted into adjacent test slots 500 in the same test rack 100. Retracting the engagement elements 476 during insertion and removal, and clamping the storage device transporter 400 to the test slot 500 after the storage device transporter 400 is fully inserted into the test slot 500, as described above, can help to reduce or limit vibrations by limiting the contact and scraping between the storage device transporters 400 and the test slots 500 during insertion and removal of the storage device transporters 400. Additionally, the ability to retract the engagement elements 476 can also help to reduce particle generation that may otherwise result from scraping between the storage device transporters 400 and the test slots 500 during insertion and removal of the storage device transporters 400, which may be beneficial since particulate matter can be deleterious to the storage devices 400.

### Methods of Operation

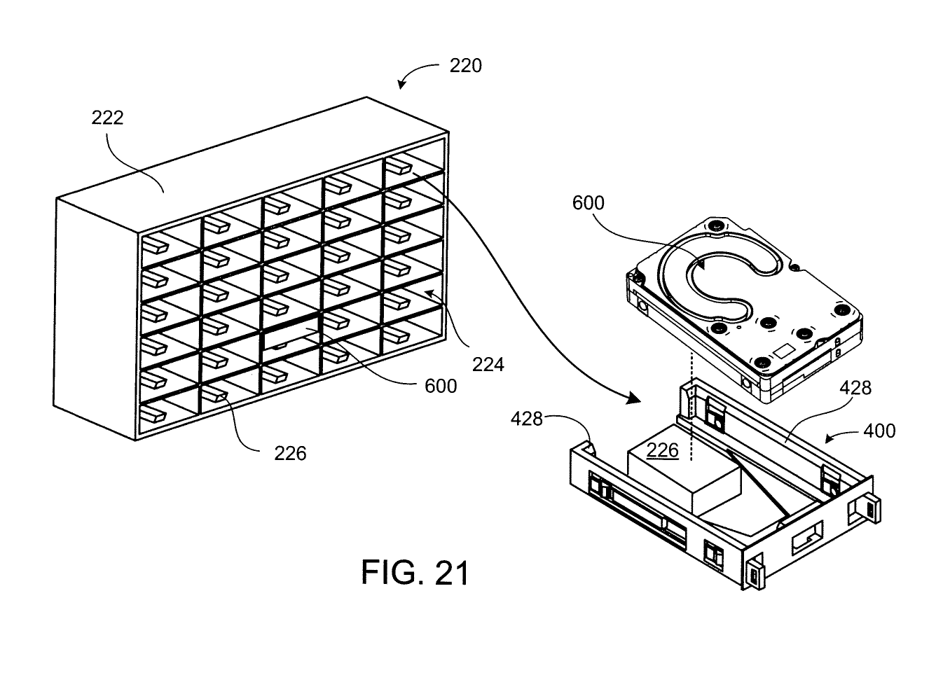

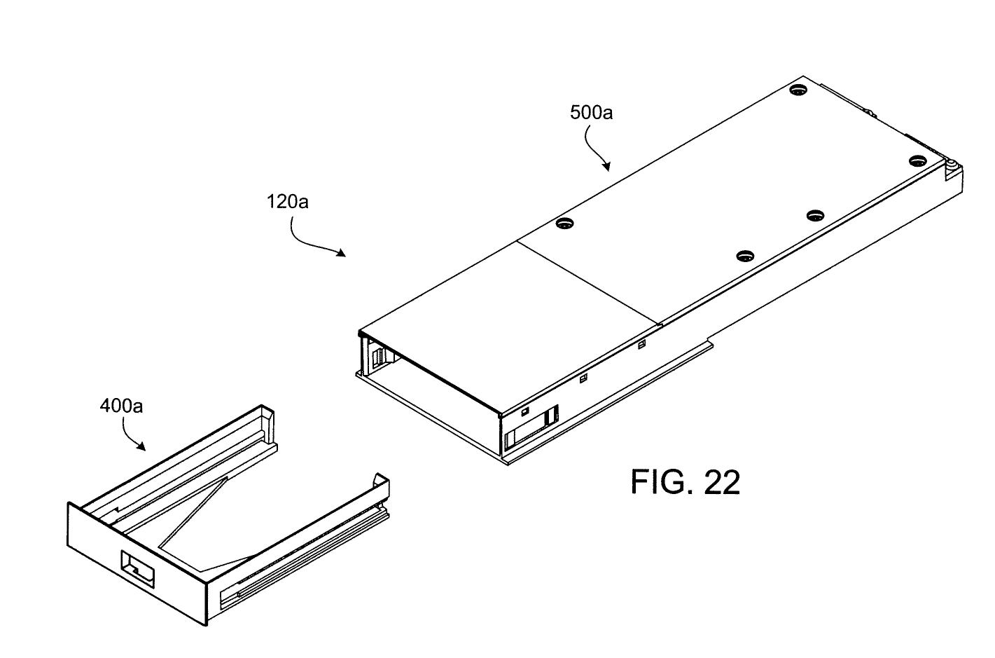

In use, one of the storage device transporters 400 is removed from one of the test slots 500 with the robot 300 (e.g., by grabbing the indentation 416 of the storage device transporter 400 with the manipulator 312 of the robot 300). As illustrated in FIG. 21, the U-shaped opening formed by the sidewalls 418 and base plate 422 allows the frame 410 to fit around the storage device support 226 in the tote 220 so that the storage device transporter 400 can be moved (e.g., via the robotic arm 310) into a position beneath one of the storage devices 600 in the tote 220. The storage device transporter 400 can then be raised (e.g., by the robotic arm 310) into a position engaging the storage device 600. As the storage device transporter 400 is raised, the lead-ins 428 on the sidewalls 418 aid in centering a storage device 600 in the frame 410.

With the storage device 600 in place within the storage device transporter 400, the storage device transporter 400 can be moved by the robotic arm 310 to position the frame 310 and the storage device 600 within one of the test slots 500. The manipulator 312 is operable to control actuation of the clamping mechanism 450 (e.g., by controlling movements of the actuators 454). This allows the clamping mechanism 450 to be actuated before the storage device transporter 400 is moved from the tote 220 to the test slot 500 to inhibit movement of the storage device 600 relative to the storage device transporter 400 during the move. Prior to insertion, the manipulator 312 can again move the actuators 454 to the release position to allow for insertion of the storage device transporter 400 into one of the test slots 500. Moving the actuators 454 to the release position prior to insertion also allows the storage device 600 to move relative to the storage device transporter 400 during insertion, which can aid in aligning the storage device connector 610 with the test slot connector 524. The storage device transporter 400 and storage device 600 are advanced into the test slot 500, via movement of the robotic arm 310, until the storage device 600 is in a test position with the storage device connector 610 engaged with the test slot connector 524. Once the storage device 600 is in the test position, the actuators 454 are moved to the engaged position (e.g., by the manipulator 312) such that the first engagement members 472 engage the storage device 600 to clamp the storage device 600 against movement relative to the storage device transporter 400 and such that the second engagement members 476 engage the engagement features 527 in the test slot 500 to inhibit movement of the storage device transporter 400 relative to the test slot 500. The clamping of the storage device transporter 400 in this manner can help to reduce vibrations during testing.

Following testing, the clamping mechanism can be disengaged by moving the actuators 454 (e.g., with the manipulator 312) to the release position to disengage the engagement members 472, 476 from the storage device 600 and the test slot 500. Once the clamping mechanism 450 is disengaged the storage device transporter 400 and storage device 600 can be withdrawn from the test slot 500, e.g., by engaging the indentation 416 in the face plate 412 with the manipulator 312 and pulling the storage device transporter 400 out of the test slot 500 with the robotic arm 310. During withdrawal, the back hooks 426 of the sidewalls 418 can help in disengaging the storage device connector 610 from the test slot connector 524.

The storage device transporter 400 and the tested storage device 600 can then be returned to the loading station 200 with the robotic arm 310. In some cases, for example, once the storage device transporter 400 is sufficiently withdrawn from the test slot 500, the clamping mechanism 450 can again be actuated (e.g., with the manipulator 312) before the storage device transporter 400 is moved from the test slot 500 to the loading station 200 to inhibit movement of the storage device 600 relative to the storage device transporter 400 during the move. The process can be repeated for each of the storage devices in the loading station 200.

### Other Embodiments

Other embodiments are within the scope of the following claims.

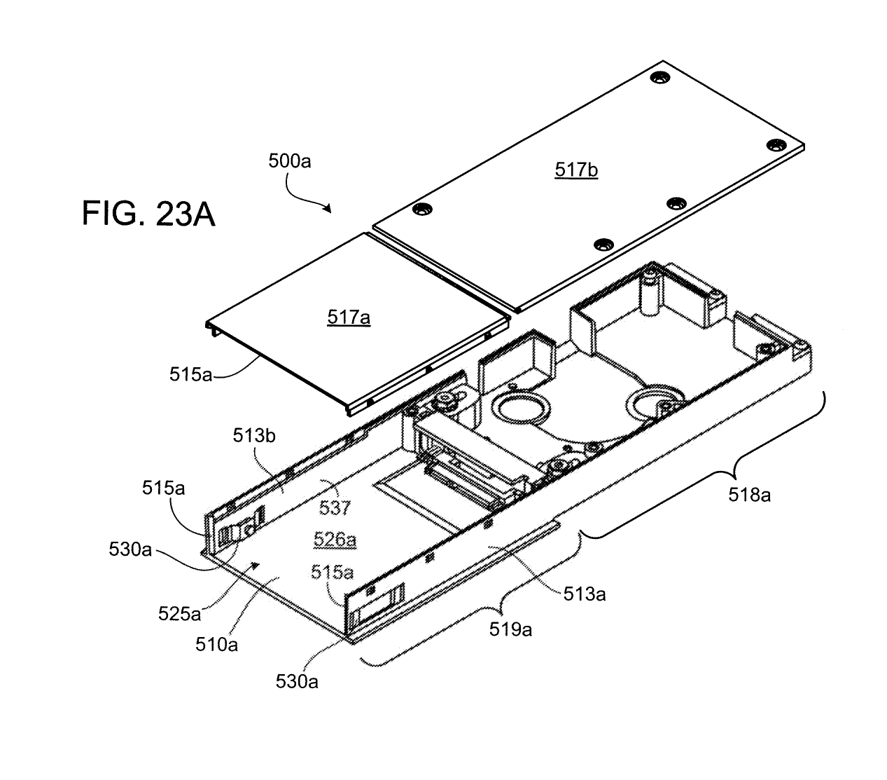

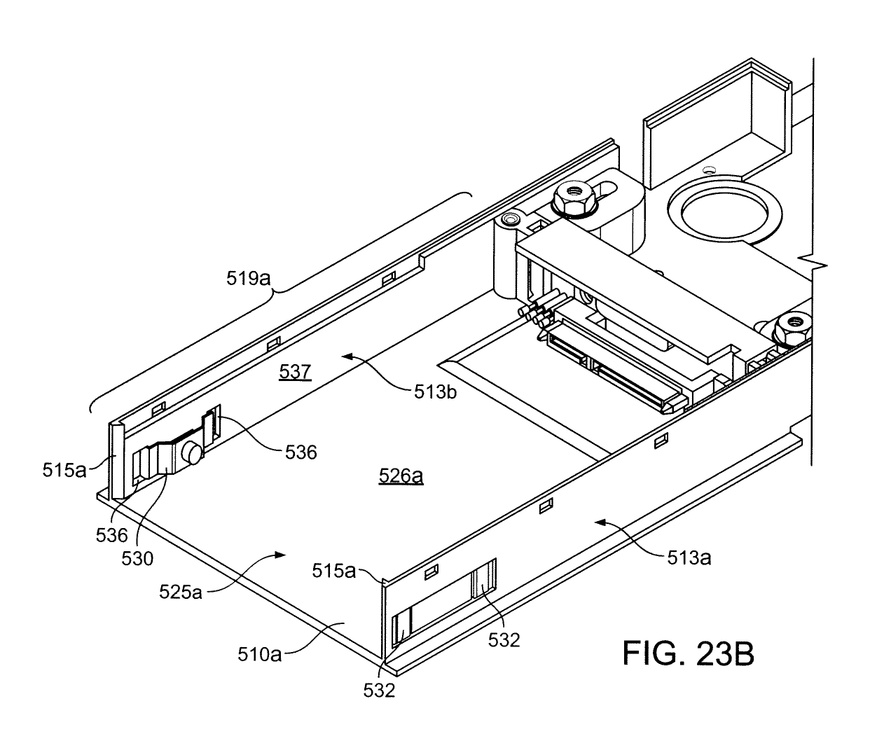

For example, while the test slot assemblies described above includes particular mechanisms for clamping with the storage device transporter, the test slot assemblies can also include other mechanisms for clamping. For example, FIG. 22 illustrates another embodiment of a test slot assembly 120a including a storage device transporter 400a and a test slot 500a in which the test slot 500a performs a clamping function. As shown in FIG. 23A, the test slot 500a includes a base 510a, upstanding walls 513a, 513b and first and second covers 517a, 517b. The test slot 500a includes a rear portion 518a and a front portion 519a. The front portion 519a of the test slot 500a defines a test compartment 526a for receiving and supporting one of the storage device transporters 400. The base 510a, upstanding walls 513a, 513b, and the first cover 517a together define a first open end 525a, which provides access to the test compartment 526a (e.g., for inserting and removing the storage device transporter 400a).

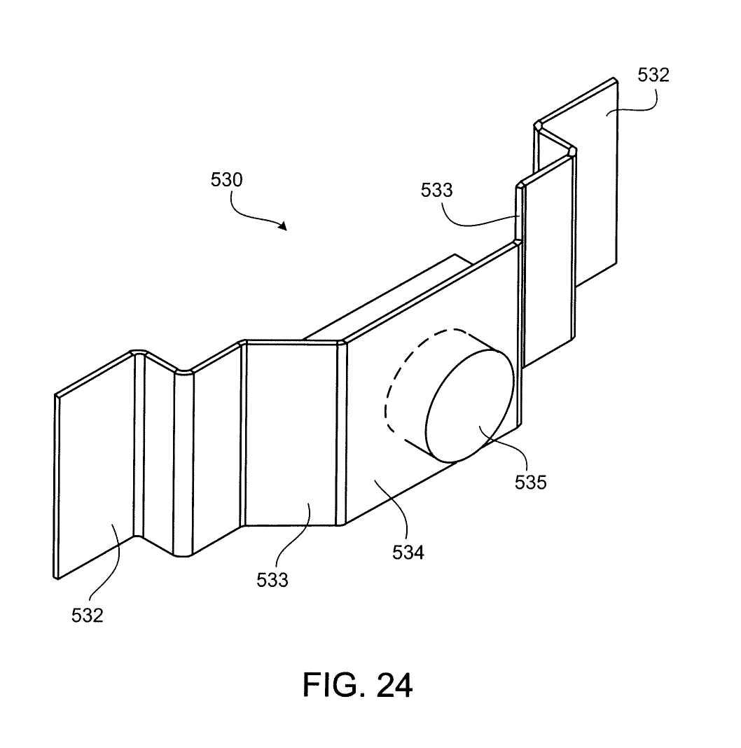

As shown in FIG. 23B, in the region of the test compartment 526a, the test slot 500a also includes clamping springs 530. As shown in FIG. 24, the clamping springs 530 include retaining tabs 532, ramp surfaces 533, and an engagement member 534 including a dampener 535. Referring again to FIG. 23B, the upstanding walls 513a, 513b include mounting holes 536. The retaining tabs 532 of the clamping springs 530 sit within the mounting holes 536 and retain the clamping springs 530 in place on inner surfaces 537 of the upstanding walls 513a, 513b.

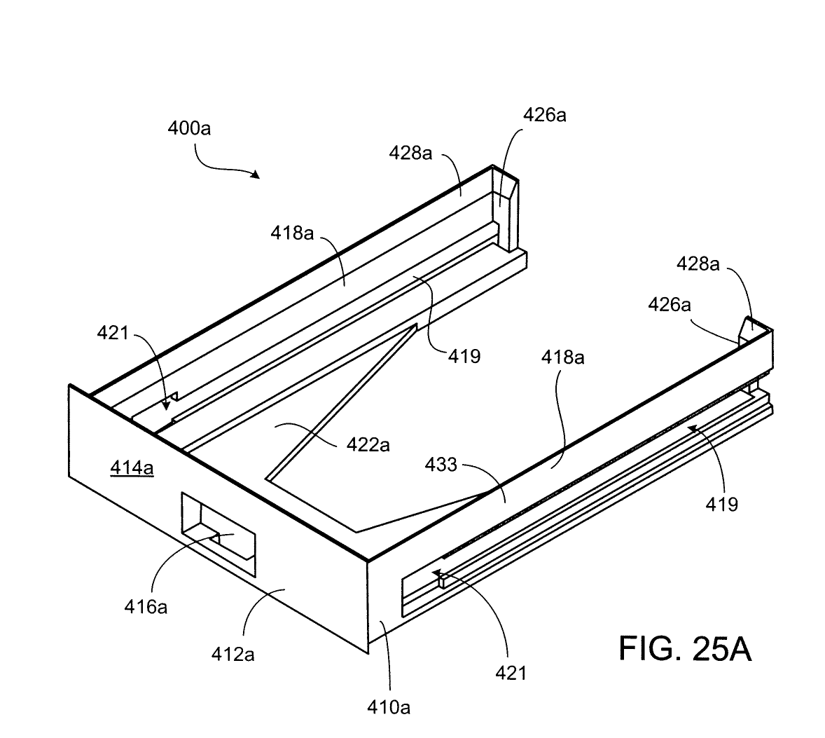

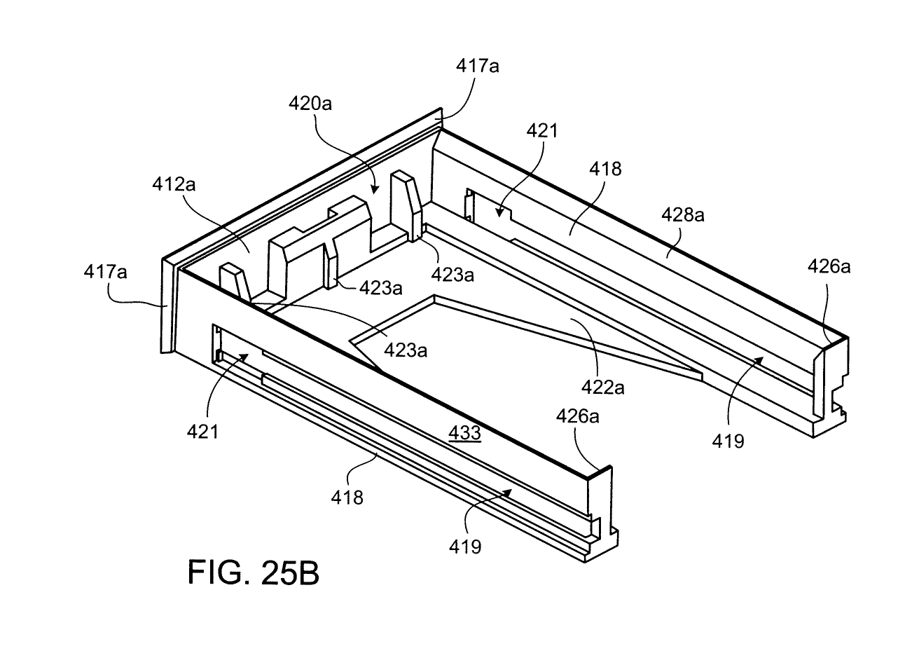

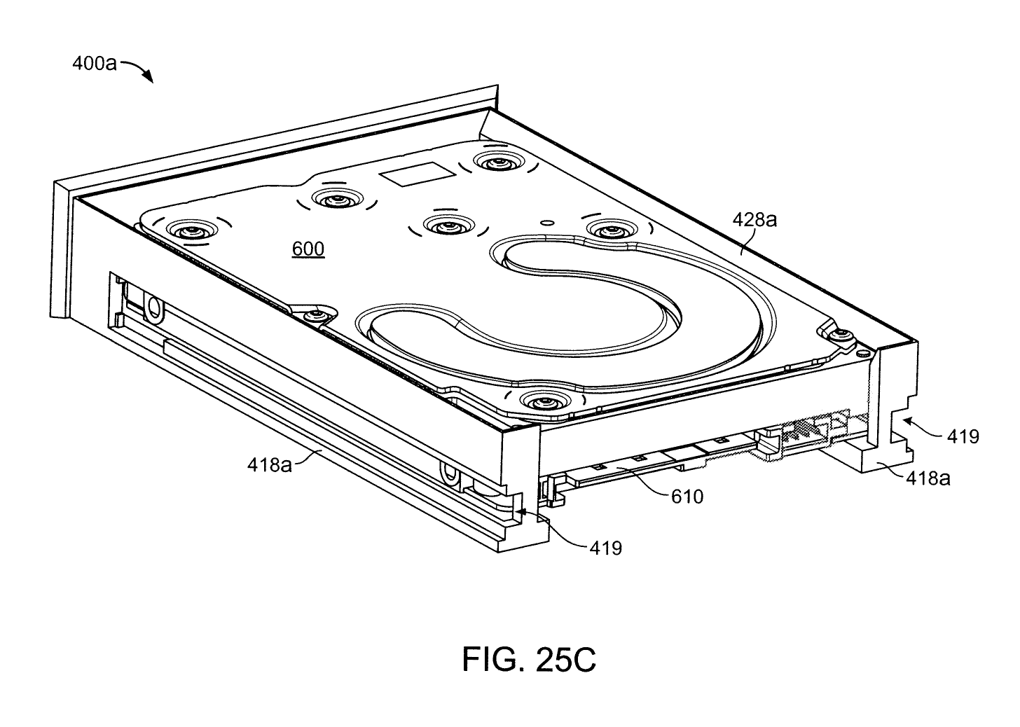

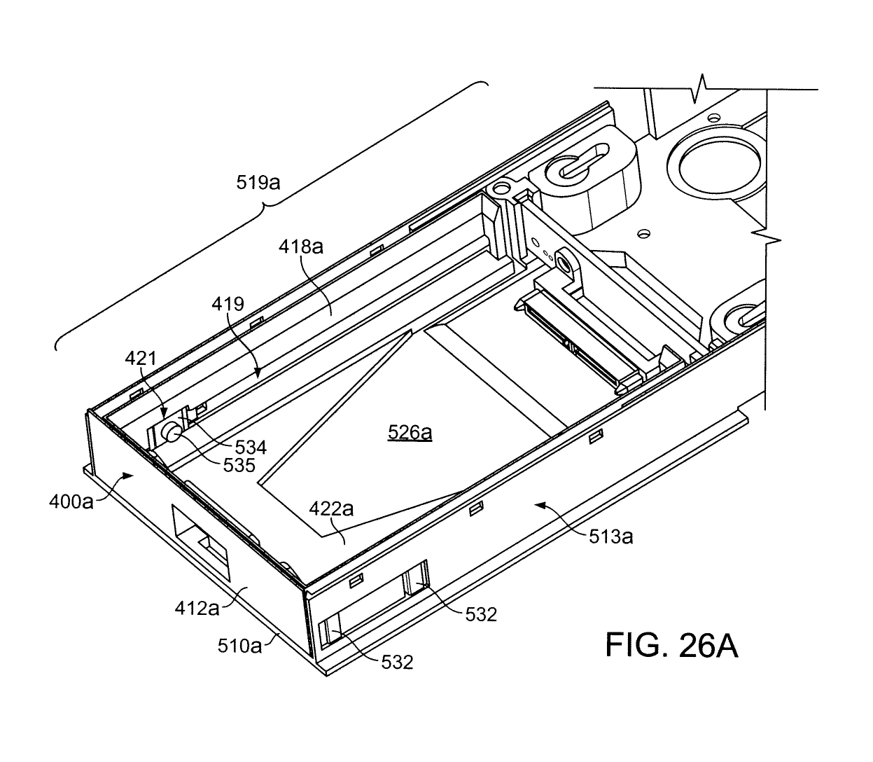

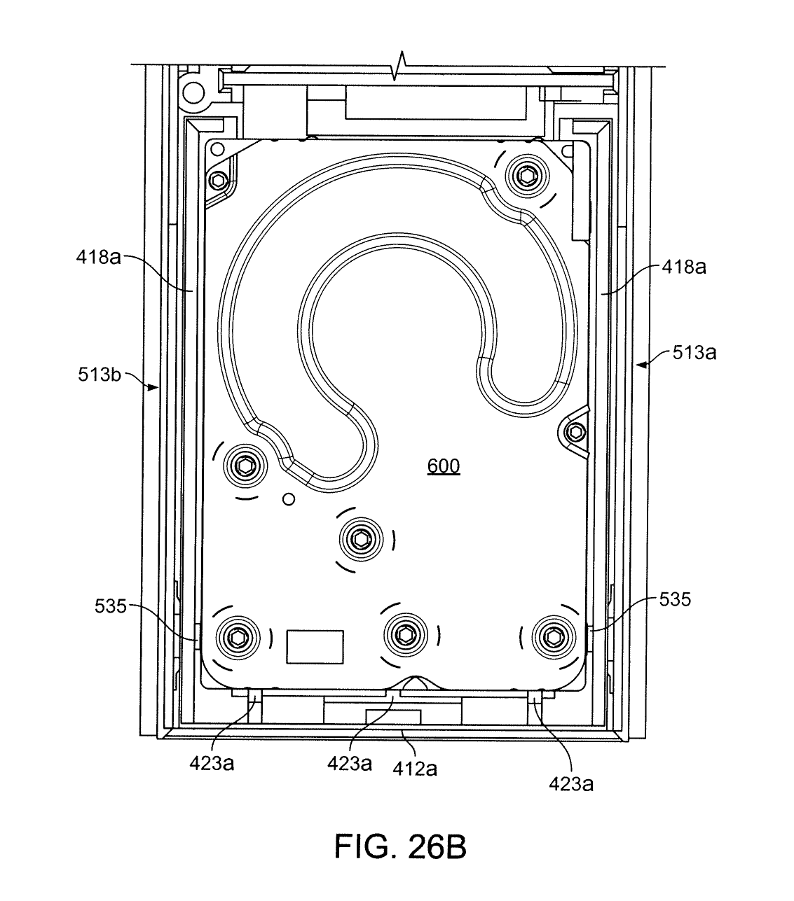

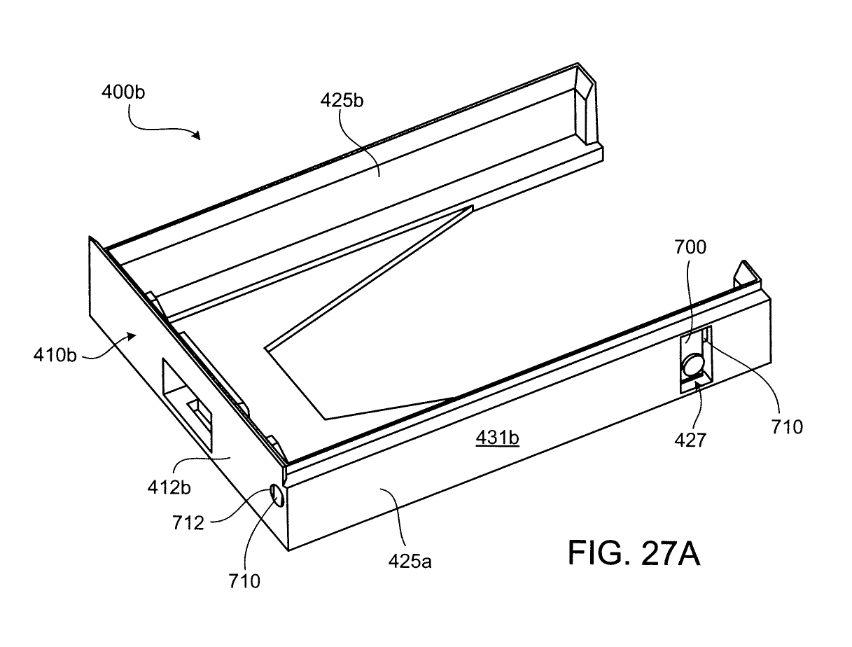

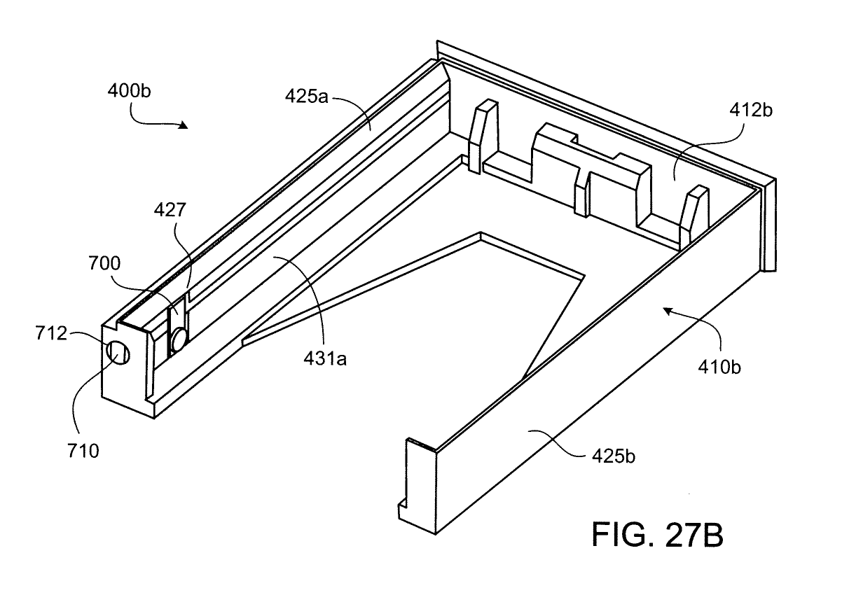

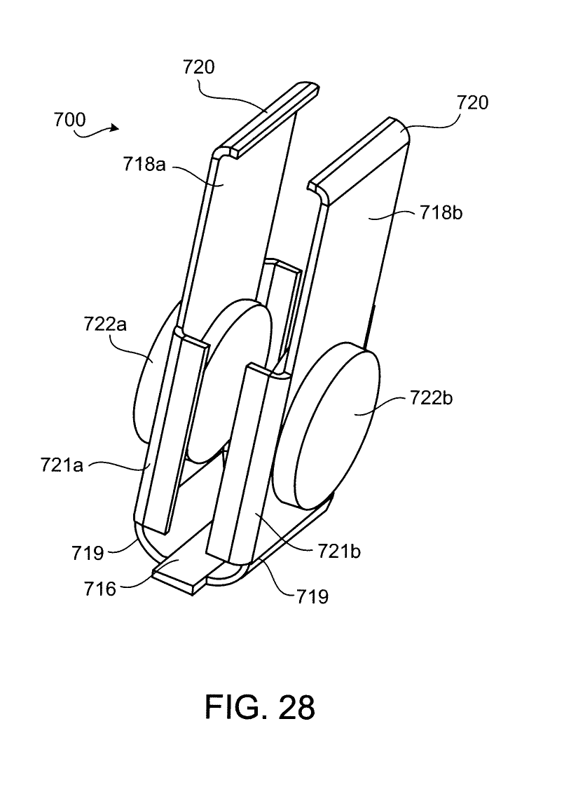

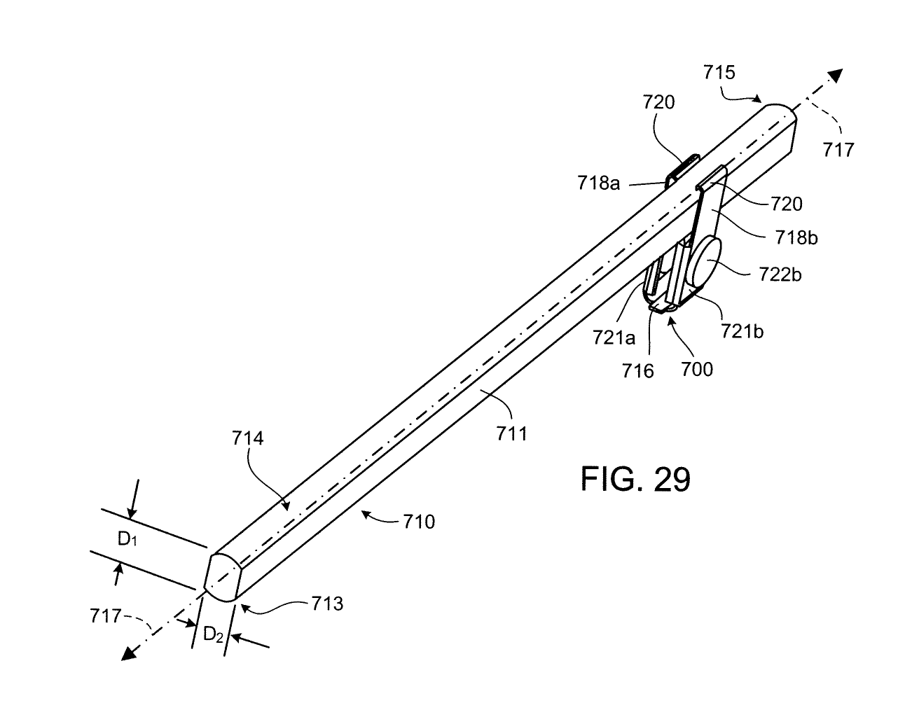

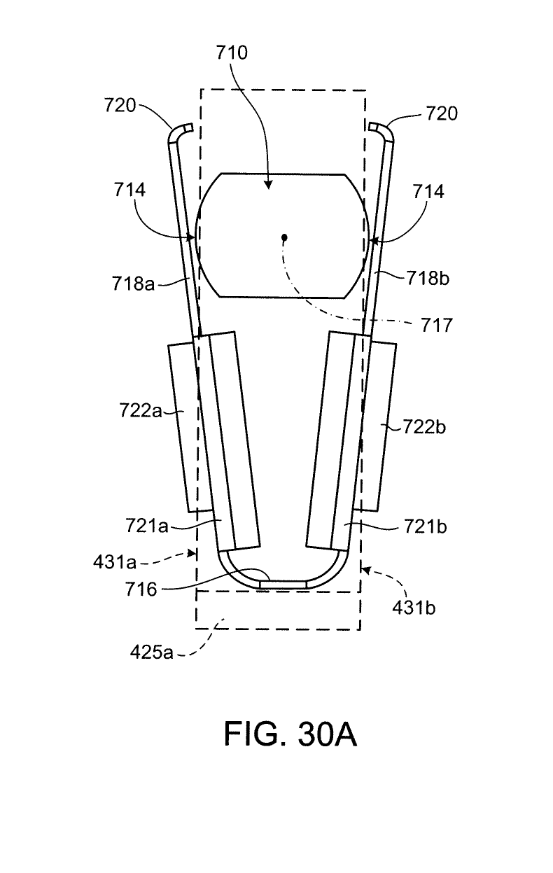

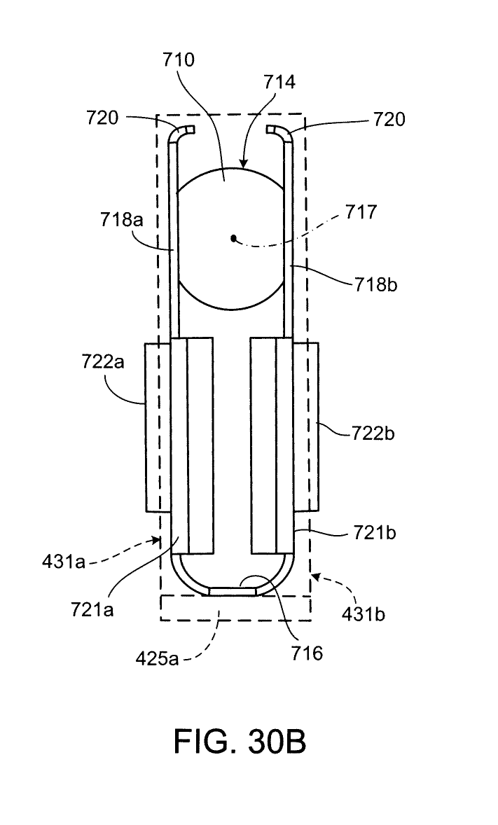

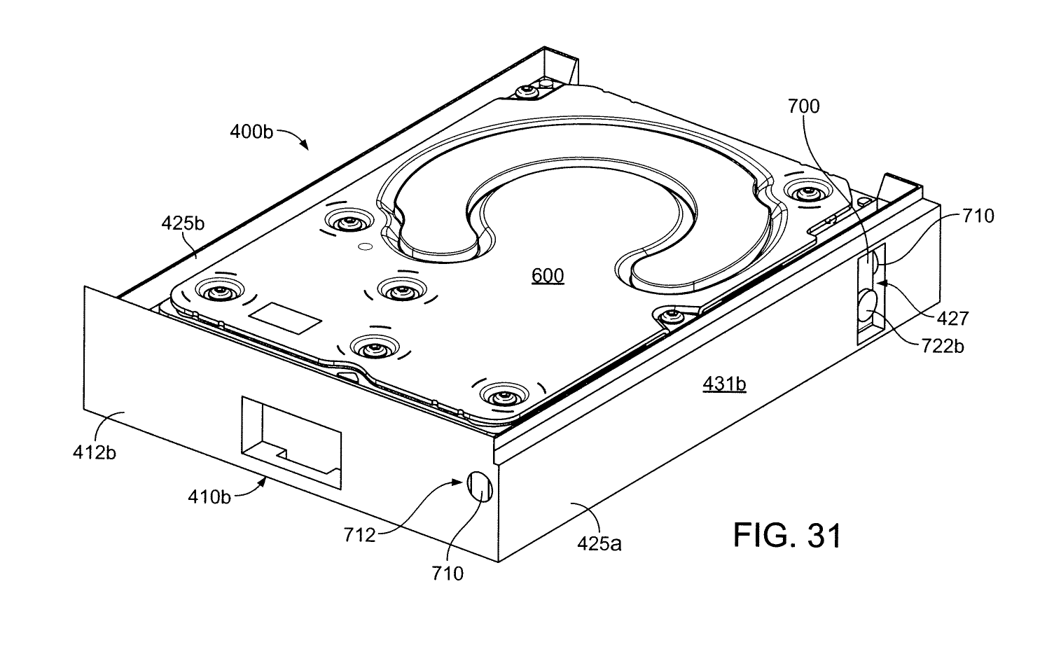

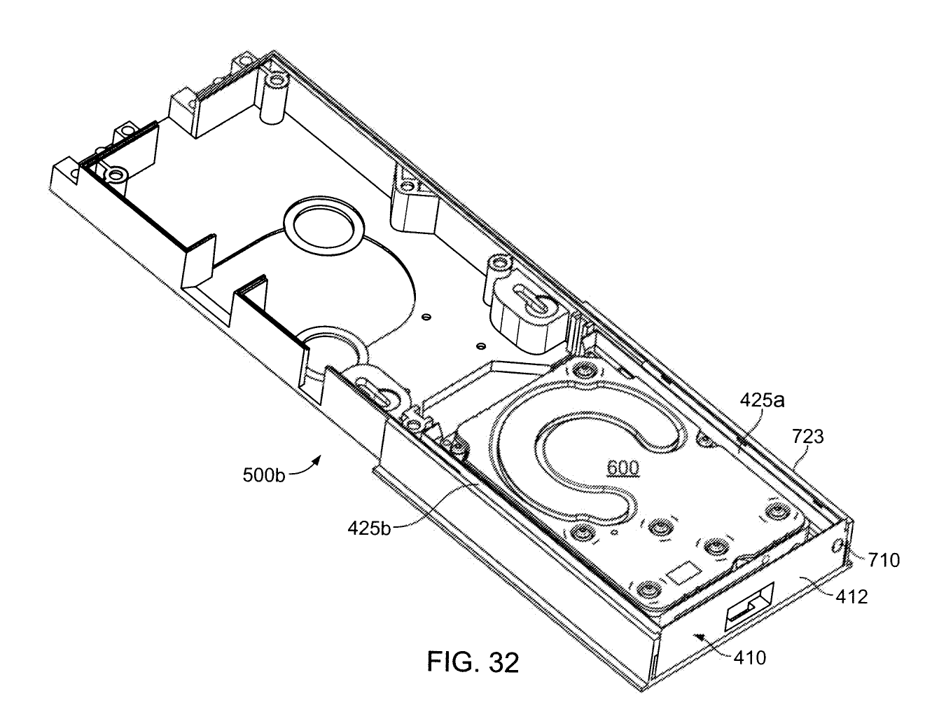

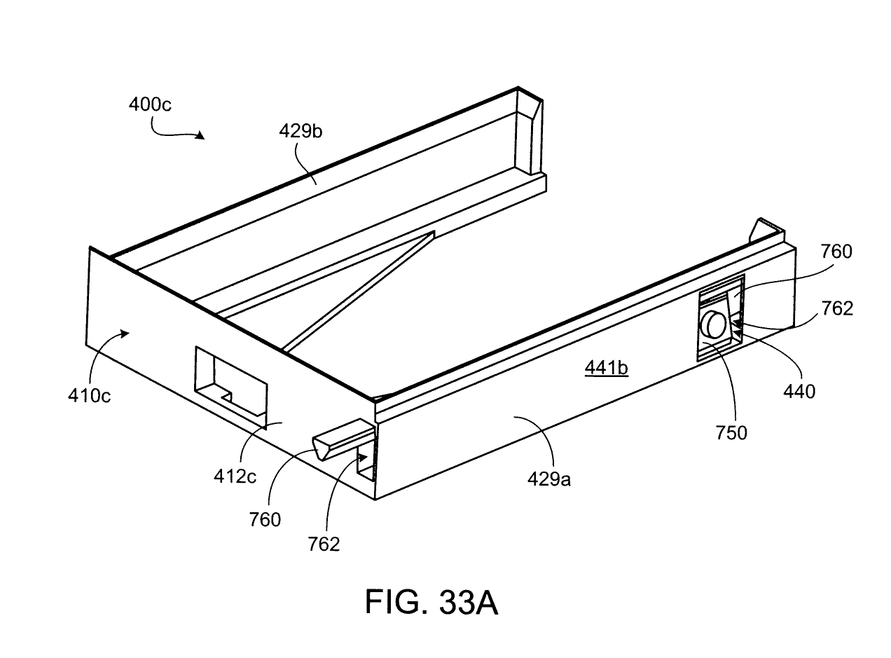

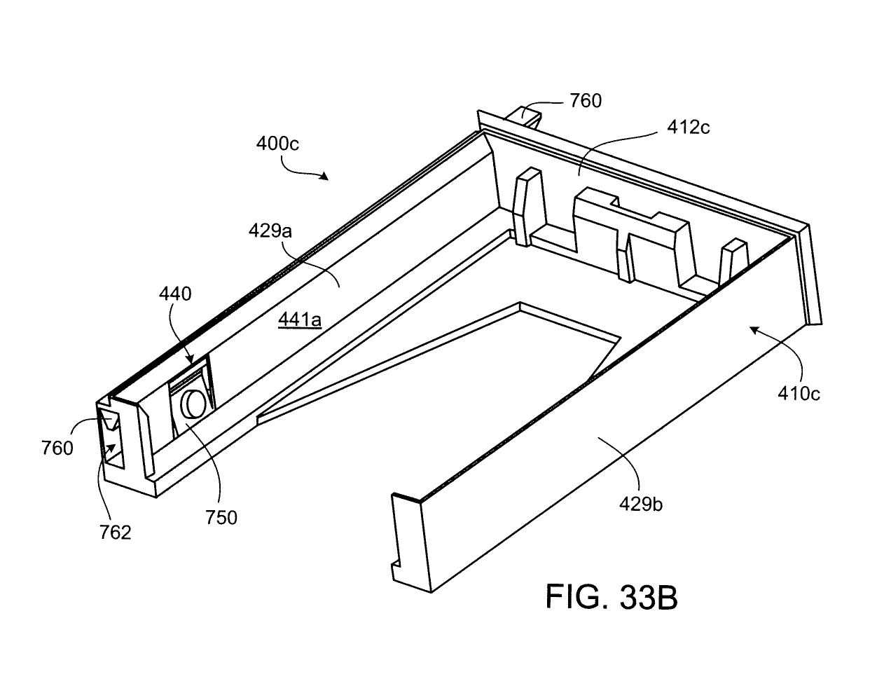

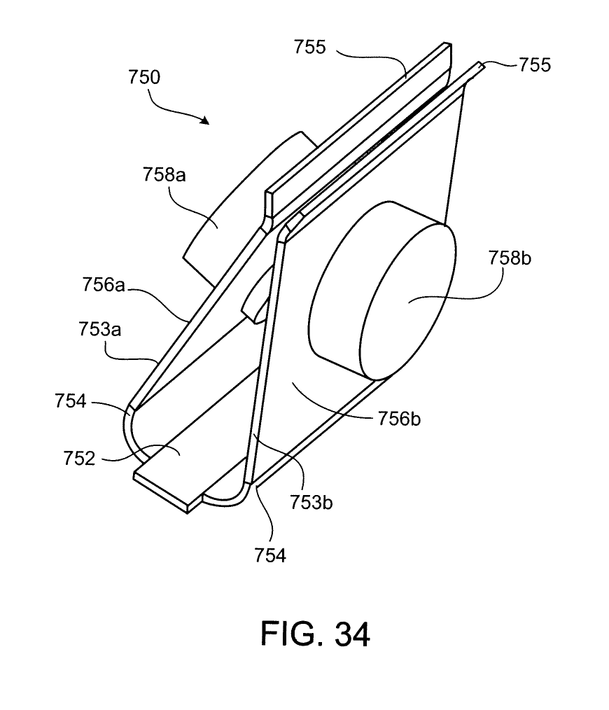

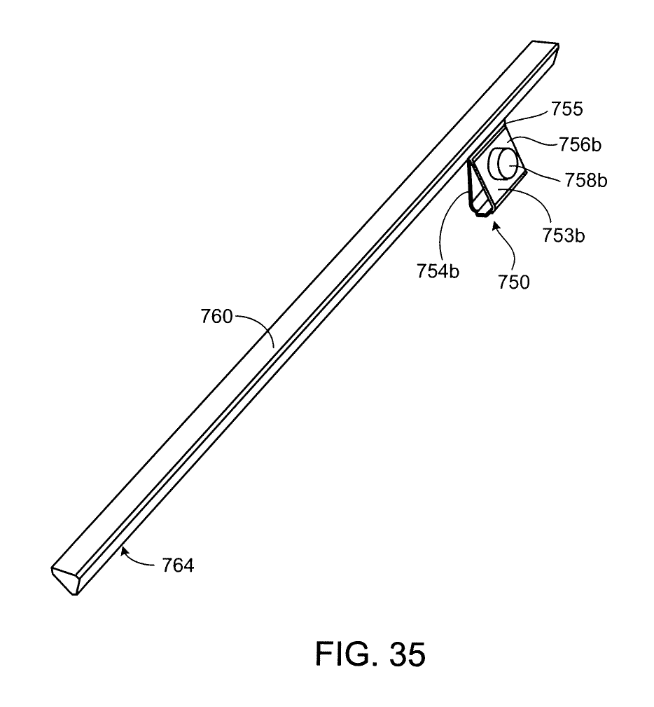

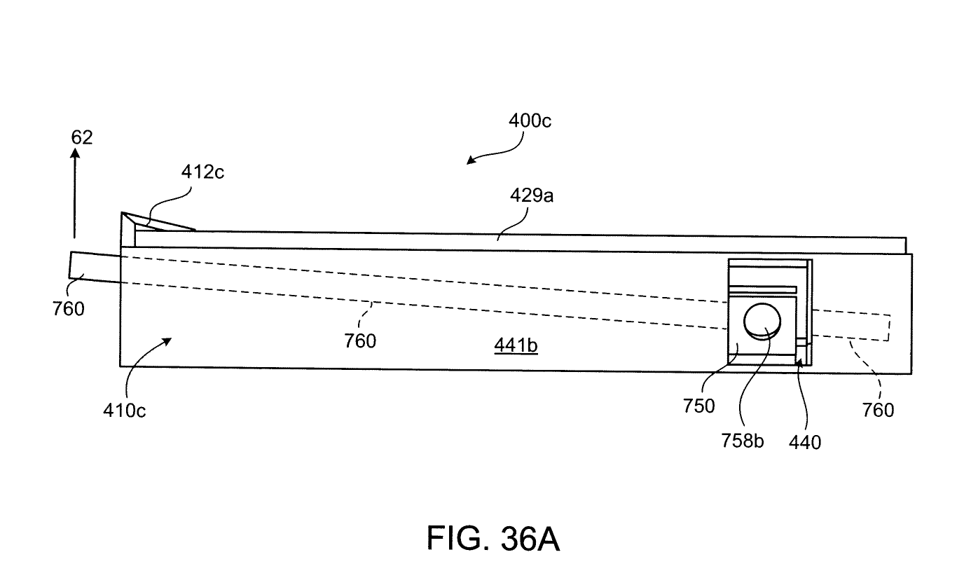

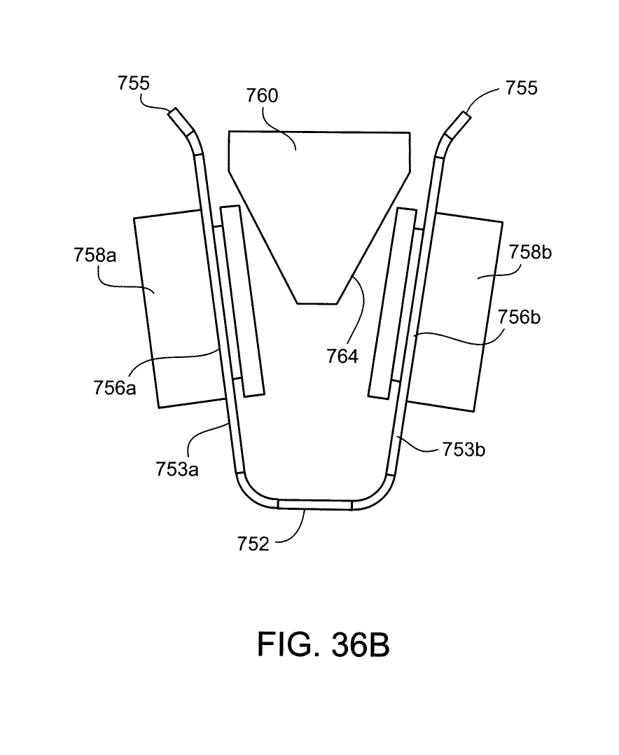

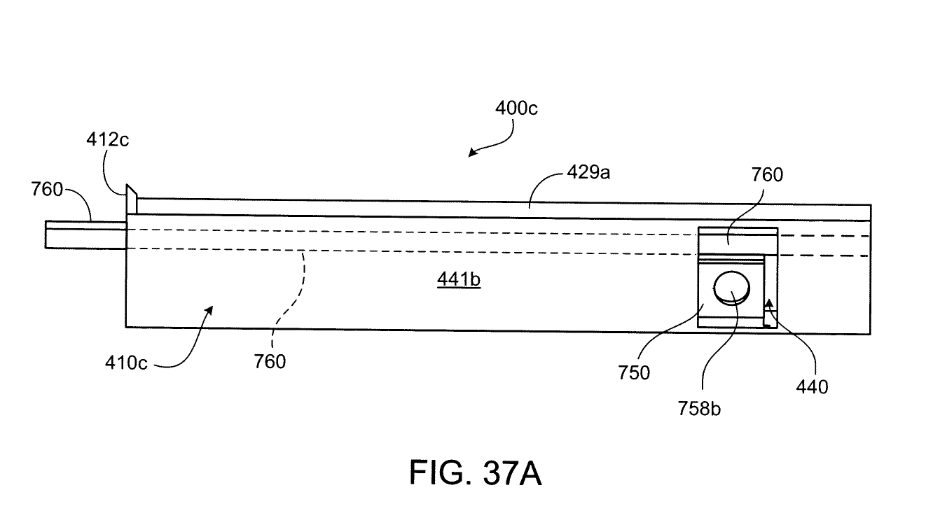

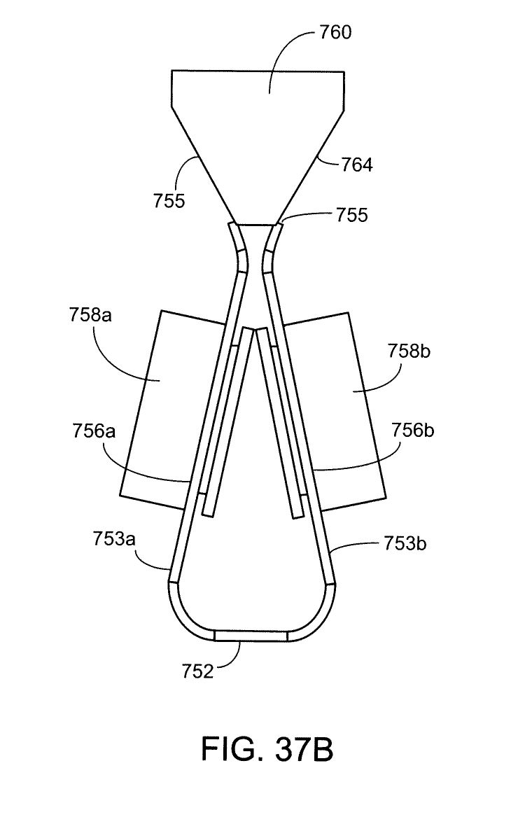

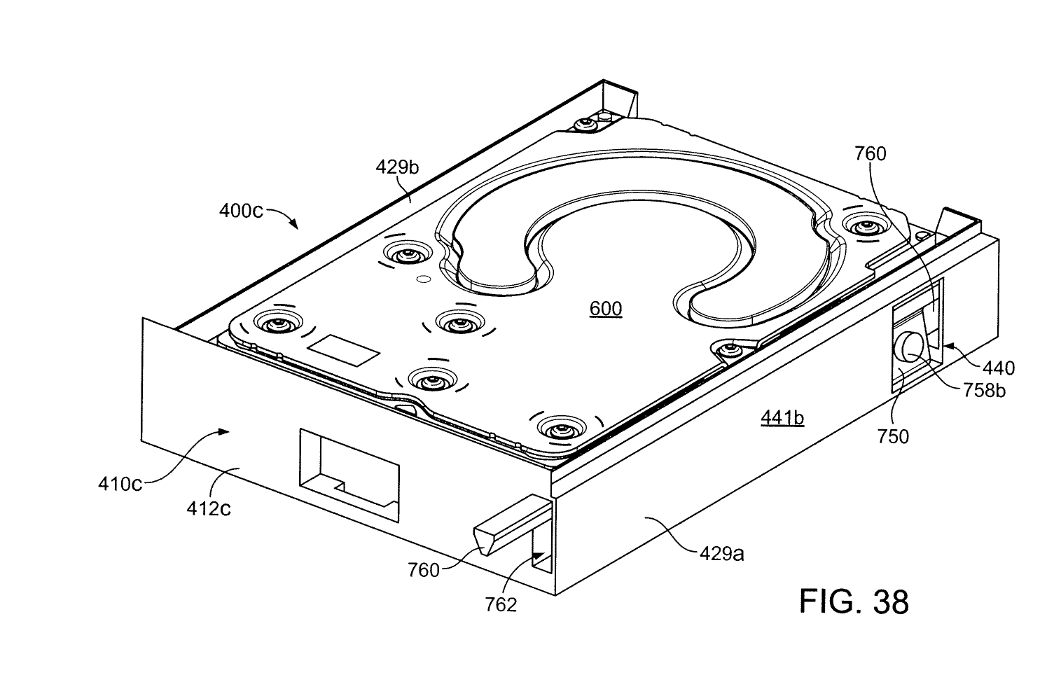

As shown in FIGS. 25A and 25B, the storage device transporter 400a generally includes a frame 410a. The frame 410a includes a face plate 412a. Along a first surface 414a, the face plate 412a defines an indentation 416a. The indentation 416a is releasably engageable by a mating protrusion on the manipulator 312 of the robotic arm 310, which allows the robotic arm 310 to grab and move the storage device transporter 400a. The face plate 412a also includes beveled edges 417a. When the storage device transporter 400a is inserted into one of the test slots 500a, the beveled edges 417a of the face plate 412a abut complimentary beveled edges 515a of the test slot 500a to form a seal, which helps to inhibit the flow of air into and out of the test slot 500a.

Referring still to FIGS. 25A and 25B, the frame 410a also includes a pair of sidewalls 418a, which extend outwardly from a second surface 420a of the face plate 412a, and a base plate 422a that extends between and connects the sidewalls 418a. As shown in FIG. 25B, along the second surface 420a, the face plate 412a defines projections 423a, which can aid in applying force to the storage device 600a as the storage device transporter 400a is inserted into the test slot 500a.

As shown in FIG. 25C, the sidewalls 418a are spaced to receive a storage device 600 therebetween, and define surfaces 424a for supporting a storage device 600. The sidewalls 418a also define back hooks 426a, which can be useful for extracting the storage device 600 from the test slot 500a. The sidewalls 418a also define lead-ins 428a, which can aid in centering a storage device 600 in the frame 410a.

Referring again to FIGS. 25A and 25B, the sidewalls 418a define slots 419 which extend from distal ends 436a of the side walls 418a and terminate in pass-through apertures 421. The pass through apertures 421 are sized to allow the engagement members 534 to pass therethrough. During insertion of the storage device transporter 400a into the test slot 500a outer surfaces 433 of the side walls 418a engage the ramp surfaces 533 of the clamping springs 530 causing the clamping springs 530 to be compressed and the engagement members 534 to be displaced towards the inner surfaces 537 of the upstanding walls 513a, 513b. As the storage device transporter 400a is advanced into the test slot 500a the dampeners 535 slide within the slots 419 in the side walls 418a. As shown in FIGS. 26A and 26B, when the storage device transporter 400a reaches the fully inserted position, the engagement members 534 extend through the pass through apertures 421 in the side walls 418a such that the dampeners 535 can engage a storage device 600 (FIG. 26B) carried by the storage device transporter 400a.

FIGS. 27A and 27B, illustrate another embodiment of a storage device transporter 400b having a clamping mechanism. The storage device transporter 400b includes a frame 410b having a face plate 412b and a pair of sidewalls 425a, 425b. A first one of the sidewalls 425a defines a pass-through aperture 427 which extends between inner and outer surfaces 431a, 431b of the first sidewall 425a. An engagement element (e.g., spring clamp 700) is disposed within the pass-through aperture 427.

As shown in FIG. 28, the spring clamp 700 includes a base portion 716 and first and second spring arms 718a, 718b each having a proximal end 719 connected to the base portion 716 and a displaceable distal end 720. The first spring arm 718a includes a first engagement member 721 a having a first dampener 722a, and the second spring arm 718b includes a second engagement member 721b having a second dampener 722b. An actuator 710 is operatively associated with the spring clamp 700. The actuator 710 passes through the face plate 412b and into an actuator slot 712 in the first sidewall 425a. As shown in FIG. 29, the actuator 710 has an elongate body 711 extending from a proximal end 713 to a distal end 715 along a first axis 717. Along its length the actuator 710 has a cross-section that includes a broad dimension D1 and a narrow dimension D2.

The actuator 710 is rotatable, about the first axis 717, within the actuator slot 712 between an engaged and a release position to initiate movements of the spring clamp 700. As shown in FIG. 30A, in the engaged position, cam surfaces 714 of the actuator 710 engage the spring clamp 700 to cause the displaceable distal ends of the spring arms 720 to extend outwardly from the inner and outer surfaces 431a, 431b of the first sidewall 425a (shown hidden). The displaceable distal ends 720 of the spring arms 720 can also be retracted by rotating the actuator 710 to the release position, as shown in FIG. 30B. When the actuator 710 has been rotated to the release position, the displaceable distal ends of the spring arms 720 are allowed to retract.

When the actuator 710 is in the release position, with the spring clamp 700 retracted, a storage device 600 can be inserted into the frame 410b between the sidewalls 425a, 425b, as shown in FIG. 31. Once a storage device 600 is inserted in the frame 410b, the actuator 710 can be rotated towards the engaged position to displace the first engagement member into contact with the storage device 600 to clamp the storage device 600 against movement relative to the frame 410b. In a similar manner, the storage device transporter 400b can also be clamped within a test slot. For example, with a storage device 600 in the frame 410b and with the actuator 710 in the release position, the storage device transporter 400b can be inserted into a test slot 500b, as shown in FIG. 32 (test slot shown with covers removed for clarity). With the storage device transporter 400b in a fully inserted position within the test slot 500b (i.e., with the storage device connector mated with the test slot connector) the actuator 710 can be rotated towards the engaged position to displace the first and second engagement members 721a, 721b to extend outwardly from the inner and outer surfaces of the first sidewall 425a. In this position, the second engagement member 721b of the spring clamp 700 extends outwardly from the outer surface 431b of first sidewall 425a and engages a wall 723 of the test slot 500b, thereby clamping the storage device transporter 400b against movement relative to the test slot 500b. At the same time, the first engagement member 721 a of the spring clamp 700 extends outwardly from the inner surface 431 a of the first sidewall 425a and engages the storage device 600 to clamp the storage device 600 against movement relative to the storage device transporter 400b.

FIGS. 33A and 33B illustrate yet another embodiment of a storage device transporter 400c having a clamping mechanism (e.g. for clamping a storage device within the storage device transporter and/or for clamping the storage device transporter within a test slot). As shown in FIGS. 33A and 33B, the storage device transporter 400c includes a frame 410c having a face plate 412c and a pair of sidewalls 429a, 429b. A first one of the sidewalls 429a defines a pass-through aperture 440 which extends between inner and outer surfaces 441a, 441b of the first sidewall 429a. An engagement element (e.g., spring clamp 750) is disposed within the pass-through aperture 427.

As shown in FIG. 34, the spring clamp 750 includes a base portion 752 and first and second spring arms 753a, 753b each having a proximal end 754 connected to the base portion 752 and a displaceable distal end 755. The first spring arm 753a includes a first engagement member 756a having a first dampener 758a, and the second spring arm 753b includes a second engagement member 756b having a second dampener 758b.

An actuator 760 is operatively associated with the spring clamp 750. The actuator 760 passes through the face plate 412c and into an actuator slot 762 in the first sidewall 429a. As shown in FIG. 35, along its length the actuator 760 has a cross-section that defines a wedge 764.

The actuator 760 is pivotable within the actuator slot 762 between an engaged position and a release position. As illustrated by FIGS. 36A and 36B, in the engaged position, the wedge 764 of the actuator 760 engages the spring clamp 750 to cause the distal ends 755 of the spring arms 753a, 753b to extend outwardly from the inner and outer surfaces 441a, 441b of the first sidewall 429a. Thus, the spring clamp 750 can be actuated by pushing and/or pulling a proximal end of the actuator 765 upwards (arrow 62) to force a distal end of the actuator 760 towards the spring clamp 750.

The distal ends 755 of the spring arms 753a, 753b can also be retracted by pivoting the actuator 760 to the release position, as shown in FIGS. 37A and 37B. When the actuator 760 has been rotated to the release position, the distal ends 755 are allowed to retract.

When the actuator 760 is in the release position, with the spring clamp 760 retracted, a storage device 600 can be inserted into the frame 410c between the sidewalls 429a, 429b, as shown in FIG. 38. Once a storage device 600 is inserted in the frame 410c, the actuator 760 can be moved towards the engaged position to displace the first engagement member 756a into contact with the storage device 600 to clamp the storage device 600 against movement relative to the frame 410c. In a similar manner, the storage device transporter 400c can also be clamped within a test slot. For example, with a storage device 600 in the frame 410c and with the actuator 760 in the release position, the storage device transporter 400c can be inserted into a test slot. With the storage device transporter 400c in a fully inserted position within the test slot, the actuator 760 can be pivoted towards the engaged position to displace the distal ends 755 of the spring arms 753a, 753b to extend outwardly from the inner and outer surfaces 441a, 441b of the first sidewall 429a. In this position, the second engagement member 756b of the spring clamp 750 extends outwardly from the outer surface 441b of first sidewall 429a and engages the test slot, thereby clamping the storage device transporter 400c against movement relative to the test slot. At the same time, the first engagement member 756a of the spring clamp 750 extends outwardly from the inner surface 441a of the first sidewall 429a and engages the storage device 600 to clamp the storage device 600 against movement relative to the storage device transporter 400c.

Elements of different embodiments may be combined to form combinations not specifically described herein. Other details and features combinable with those described herein may be found in the following U.S. patent applications filed concurrently herewith, entitled “DISK DRIVE TESTING”, with attorney docket number: 18523-062001, inventors: Edward Garcia et al., and having assigned Ser. No. 11/958,788; and “DISK DRIVE TESTING”, with attorney docket number: 18523-064001, inventors: Edward Garcia et al., and having assigned Ser. No. 11/958,817, the entire contents of the aforementioned applications are hereby incorporated by reference.

The claims are not limited to the embodiments described herein.

1. A storage device transporter for transporting a storage device and for mounting a storage device within a test slot, the storage device transporter comprising:
a frame configured to receive and support a storage device, the frame comprising
sidewalls configured to receive a storage device therebetween and sized to be inserted into a test slot along with a storage device; and
a clamping mechanism operatively associated with at least one of the sidewalls and comprising:
a first engagement element; and
a first actuator operable to initiate movements of the first engagement element, wherein the first actuator is operable to move the first engagement element into engagement with a test slot after a storage device being supported by the frame is arranged in a test position in a test slot.

2. The storage device transporter of claim 1, wherein the first actuator is operable to move the first engagement element into engagement with a storage device being supported by the frame.

3. The storage device transporter of claim 1, wherein the first engagement element comprises first and second engagement members, and wherein the first actuator is operable to initiate movements of the first and second engagement members.

4. The storage device transporter of claim 3, wherein the first actuator is operable to move the first engagement member into engagement with a test slot after a storage device being supported by the frame is arranged in a test position in a test slot, and wherein the first actuator is operable to move the second engagement member into engagement with a storage device being supported by the frame.

5. The storage device transporter of claim 3, wherein the second engagement member comprises a dampener.

6. The storage device transporter of claim 5, wherein the dampener comprises a dampening material selected from the group consisting of thermoplastics and thermosets.

7. The storage device transporter of claim 5, wherein the dampener comprises an isolating or dampening material.

8. The storage device transporter of claim 3, wherein the first actuator is operable to move the first and second engagement members in substantially opposite directions relative to each other.

9. The storage device transporter of claim 8, wherein the first actuator is operable to move the first and second engagement members substantially simultaneously.

10. The storage device transporter of claim 1, wherein the first engagement element comprises a protuberance configured to engage a mating feature in a test slot.

11. The storage device transporter of claim 1, wherein the first engagement element comprises a dampener.

12. The storage device transporter of claim 11, wherein the dampener comprises a dampening material selected from the group consisting of thermoplastics and thermosets.

13. The storage device transporter of claim 1, wherein the first engagement element comprises a spring clamp, the spring clamp comprising:
a base portion; and
first and second spring arms each comprising a proximal end connected to the base portion and a displaceable distal end.

14. The storage device transporter of claim 13, wherein the actuator is operable to initiate movements of the distal ends of the first and second spring arms.

15. The storage device transporter of claim 1, wherein the first actuator is pivotable relative to the frame to initiate movements of the first engagement element.

16. The storage device transporter of claim 1, wherein the first actuator comprises an elongate body extending from a proximal end to a distal end along a first axis, and wherein the first actuator is rotatable about the first axis to initiate movements of the first engagement member.

17. The storage device transporter of claim 1, wherein the first actuator is linearly displaceable relative to the frame to initiate movements of the first engagement member.

18. The storage device transporter of claim 1, wherein a first one of the sidewalls defines a first actuator slot, and wherein the first actuator is at least partially disposed within the first actuator slot.

19. The storage device transporter of claim 18, wherein the first actuator is moveable within the first actuator slot to initiate movements of the first engagement member.

20. The storage device transporter of claim 1, wherein the clamping mechanism further comprises a second engagement element, and wherein the first actuator is operable to initiate movements of the second engagement element.

21. The storage device transporter of claim 20, wherein the first actuator is operable to move the second engagement element into engagement with a test slot after a storage device being supported by the frame is arranged in a test position in the test slot.

22. The storage device transporter of claim 20, wherein the first actuator is operable to move the second engagement element into engagement with a storage device being supported by the frame.

23. The storage device transporter of claim 1, wherein the clamping mechanism further comprises:
a second engagement element; and
a second actuator operable to initiate movements of the second engagement element.

24. The storage device transporter of claim 23, wherein the second actuator is operable independently of the first actuator to initiate movements of the second engagement element.

25. The storage device transporter of claim 23, wherein the second actuator is operable to move the second engagement element into engagement with a test slot after a storage device being supported by the frame is arranged in a test position in a test slot.

26. The storage device transporter of claim 23, wherein the second actuator is operable to move the second engagement element into engagement with a storage device being supported by the frame.

27. The storage device transporter of claim 1, wherein the first actuator defines actuating features for initiating movements of the first engagement element.

28. The storage device transporter of claim 27, wherein the actuating features comprise wedges and recesses.

29. The storage device transporter of claim 1, wherein the frame comprises a base plate connected to the sidewalls, and wherein the sidewalls and the base plate together define a substantially U-shaped opening for capturing a storage device off of a support.

30. A storage device test slot comprising:
a housing defining:
a test compartment for receiving and supporting a storage device transporter carrying a storage device for testing, and
an open end providing access to the test compartment for insertion and removal of storage device transporter carrying a storage device for testing; and
a first engagement element mounted to the housing, wherein the first engagement element is configured to engage a storage device carried by a storage device transporter when a storage device transporter is inserted in the test compartment.

31. The storage device test slot of claim 30, wherein the first engagement element comprises a clamping spring.

32. The storage device test slot of claim 30, wherein the first engagement element comprises a dampener.

33. The storage device test slot of claim 32, wherein the dampener is configured to engage a storage device carried by a storage device transporter when a storage device transporter is inserted in the test compartment.

34. The storage device test slot of claim 32, wherein the dampener comprises a dampening material selected from the group consisting of thermoplastics and thermosets.

35. A storage device testing system comprising:
automated machinery;
a storage device transporter comprising:
a frame configured to receive and support a storage device, wherein the automated machinery is configured to releasably engage the frame to control movement of the storage device transporter;
a loading station for storing storage devices to be tested; and
a test slot configured to receive and support a storage device transporter carrying a storage device, wherein the automated machinery is operable to remove storage devices from the loading station utilizing the storage device transporter and insert the storage device transporter, having a storage device therein, into the test slot.

36. The storage device testing system of claim 35, wherein the automated machinery comprises a robot, the robot comprising:
a moveable arm; and
a manipulator connected to the moveable arm, wherein the manipulator is configured to releasably engage the frame to control movement of the storage device transporter.

37. The storage device testing system of claim 36, wherein the robot is operable to remove storage devices from the loading station utilizing the storage device transporter and insert the storage device transporter, having a storage device therein, into the test slot.

38. The storage device testing system of claim 35, wherein the frame comprises a face plate defining an indentation configured to be releasably engageable by the automated machinery.

39. The storage device testing system of claim 35, wherein the frame comprises a clamping mechanism comprising:
a first engagement element; and
a first actuator operable to initiate movements of the first engagement element, wherein the first actuator is operable to move the first engagement element into engagement with the test slot after a storage device being supported by the frame is arranged in a test position in the test slot.

40. The storage device testing system of claim 39, wherein the automated machinery is configured to control operation of the clamping mechanism.

41. The storage device testing system of claim 39, wherein the frame comprises sidewalls configured to receive a storage device therebetween and sized to be inserted into a test slot along with a storage device for testing of the storage device, and wherein the clamping mechanism is operatively associated with at least one of the sidewalls.

42. A storage device transporter for transporting a storage device and for mounting a storage device within a test slot, the storage device transporter comprising:
a frame comprising:
sidewalls configured to receive a storage device therebetween and sized to be inserted into a test slot along with a storage device; and
a base plate connecting the sidewalls, wherein the sidewalls and the base plate together define a substantially U-shaped opening for capturing a storage device off of a support.

43. A method of testing a storage device, the method comprising:
actuating automated machinery to engage a storage device transporter;
capturing a storage device with the storage device transporter; and then
actuating the automated machinery to insert the storage device transporter and the captured storage device into a test slot, wherein capturing the storage device comprises moving the storage device transporter into engagement with the storage device using the automated machinery.

44. The method of claim 43, wherein actuating the automated machinery comprises actuating a robotic arm.

45. The method of claim 43, wherein the storage device transporter comprises a clamping mechanism operable to clamp the storage device transporter to the test slot, and further comprising actuating the automated machinery to operate the clamping assembly and thereby clamping the storage device transporter to the test slot after the storage device transporter and the captured storage device are inserted into the test slot.

46. The method of claim 43, wherein capturing the storage device comprises:
actuating the automated machinery to move the storage device transporter into a position underlying the storage device; and
actuating the automated machinery to raise the storage device transporter into a position engaging the storage device.

47. A method of testing a storage device, the method comprising:
actuating automated machinery to insert a storage device transporter carrying a storage device into a test slot, and
actuating the automated machinery to operate a clamping mechanism and thereby clamping the storage device transporter to the test slot after the storage device transporter and the captured storage device are inserted into the test slot.

48. The method of claim 47, wherein actuating automated machinery comprises actuating a robotic arm.

49. The method of claim 47, further comprising actuating the automated machinery to engage the clamping assembly and thereby clamping the storage device transporter to the captured storage device.

50. A test slot assembly comprising:
A.) a test slot comprising:
i.) a housing defining:
a.) a test compartment, and
b.) an open end providing access to the test compartment; and
B.) a storage device transporter comprising;
i.) a frame configured to receive and support a storage device, the frame comprising:
a.) sidewalls configured to receive a storage device therebetween and sized to be inserted into the test compartment along with a storage device; and
ii.) a clamping mechanism operatively associated with at least one of the sidewalls and comprising:
a.) a first engagement element; and
b.) a first actuator operable to initiate movements of the first engagement element, wherein the first actuator is operable to move the first engagement element into engagement with the housing after a storage device being supported by the frame is arranged in a test position in the test compartment.

51. The test slot assembly of claim 50, wherein the first engagement element comprises first and second engagement members, and wherein the first actuator is operable to initiate movements of the first and second engagement members.

52. The test slot assembly of claim 51, wherein the first actuator is operable to move the first engagement member into engagement with the test slot after a storage device being supported by the frame is arranged in a test position in the test compartment, and wherein the first actuator is operable to move the second engagement member into engagement with a storage device being supported by the frame.

53. The test slot assembly of claim 51, wherein the second engagement member comprises a dampener.

54. The test slot assembly of claim 51, wherein the first actuator is operable to move the first and second engagement members in substantially opposite directions relative to each other.

55. The test slot assembly of claim 51, wherein the first actuator is operable to move the first and second engagement members substantially simultaneously.

56. The test slot assembly of claim 50, wherein the housing comprises upstanding walls configured to receive the sidewalls of the frame therebetween, wherein a first one of the upstanding walls comprises an engagement feature, and wherein the first engagement element comprises a protuberance configured to engage the engagement feature.

57. The test slot assembly of claim 56, wherein the first actuator is operable to move the protuberance into engagement with the engagement feature after the sidewalls are inserted into the test compartment.

58. A test slot assembly comprising:
A.) a storage device transporter comprising
i.) a frame configured to receive and support a storage device, the frame comprising:
a.) sidewalls configured to receive a storage device therebetween, wherein a first one of the sidewalls defines a pass-through aperture; and
B.) a housing including:
i.) a test compartment for receiving and supporting the storage device transporter, and
ii.) an open end providing access to the test compartment for insertion and removal of the storage device transporter; and
iii.) a first engagement element mounted to the housing, wherein the first engagement element is configured to extend through the pass-through aperture to engage a storage device carried by the storage device transporter when the storage device transporter is inserted in the test compartment.

59. A storage device testing system comprising:
automated machinery; and
a storage device transporter comprising:
a frame configured to receive and support a storage device, and
a clamping mechanism comprising:
a first engagement element, and
a first actuator operable to initiate movements of the first engagement element, wherein the automated machinery is configured to control operation of the clamping mechanism.

60. The storage device testing system of claim 59, wherein the automated machinery is configured to releasably engage the frame to control movement of the storage device transporter

61. The storage device testing system of claim 59, wherein the automated machinery comprises a robot, the robot comprising:
a moveable arm; and
a manipulator connected to the moveable arm, wherein the manipulator is configured to releasably engage the frame to control movement of the storage device transporter.

62. The storage device testing system of claim 61, wherein the manipulator is operable to control operation of the clamping mechanism.

63. The storage device testing system of claim 59, wherein the frame comprises a face plate defining an indentation configured to be releasably engageable by the automated machinery.

64. A method of transporting storage devices for testing, the method comprising:
actuating automated machinery and thereby moving a storage device transporter carrying a first storage device between a first test slot and a loading station; and
actuating the automated machinery to operate a clamping mechanism such that the storage device transporter is clamped to the first storage device during movement between the first test slot and the loading station.

65. The method of claim 64, wherein moving the storage device transporter between the first test slot and the loading station comprises moving the storage device transporter carrying the first storage device from the loading station to the first test slot.

66. The method of claim 64, wherein moving the storage device transporter between the first test slot and the loading station comprises moving the storage device transporter carrying the first storage device from the first test slot to the loading station.

67. The method of claim 64, wherein actuating the automated machinery to operate the clamping mechanism comprises clamping the storage device transporter to the first storage device prior to moving the storage device transporter between the first test slot and the loading station.

68. The method of claim 64, wherein actuating the automated machinery to operate the clamping mechanism comprises clamping the storage device transporter to the first storage device as the storage device transporter is being moved between the first test slot and the loading station.

69. The method of claim 64, further comprising:
actuating the automated machinery to operate the clamping mechanism and thereby unclamping the storage device transporter from the first storage device, and then
actuating the automated machinery to insert the storage device transporter and the first storage device into the first test slot.

70. The method of claim 69, further comprising actuating the automated machinery to operate the clamping mechanism and thereby clamping the storage device transporter to the first test slot after the storage device transporter and the first storage device are inserted into the first test slot.

71. The method of claim 64, further comprising:
actuating the automated machinery to operate the clamping mechanism and thereby unclamping the storage device transporter from the first test slot; and then
actuating the automated machinery to remove the storage device transporter from the first test slot.

72. The method of claim 71, further comprising:
actuating the automated machinery to operate the clamping mechanism and thereby unclamping the storage device transporter from the first storage device prior to removing the storage device transporter from the first test slot.

73. The method of claim 64, further comprising:
actuating the automated machinery to operate the clamping mechanism and thereby unclamping the storage device transporter from a second test slot; and then
actuating the automated machinery and thereby removing the storage device transporter from the second test slot.

74. The method of claim 73, further comprising capturing the first storage device from the loading station with the storage device transporter after removing the storage device transporter from the second test slot, wherein capturing the first storage device comprises moving the storage device transporter into engagement with the first storage device using the automated machinery.

75. The method of claim 73, further comprising actuating the automated machinery to operate the clamping mechanism and thereby unclamping the storage device transporter from a second storage device, and wherein removing the storage device transporter from the second test slot comprises removing the storage device transporter carrying the second storage device from the second test slot.

76. The method of claim 75, further comprising actuating the automated machinery and thereby moving the storage device transporter carrying the second storage device between the second test slot and the loading station, and
actuating the automated machinery to operate the clamping mechanism such that the storage device transporter is clamped to the second storage device during movements between the second test slot and the loading station.

77. The method of claim 76, further comprising actuating the automated machinery to insert the storage device transporter and the second storage device into a storage device receptacle at the loading station.

78. The method of claim 64, further comprising:
actuating the automated machinery to insert the storage device transporter into the first test slot; and then
actuating the automated machinery to operate the clamping mechanism and thereby clamping the storage device transporter to the first test slot after the storage device transporter is inserted into the first test slot.

79. A method of transporting storage devices for testing, the method comprising:
actuating automated machinery and thereby moving a storage device transporter carrying a first storage device between a first test slot and a second test slot; and
actuating the automated machinery to operate a clamping mechanism such that the storage device transporter is clamped to the first storage device during movement between the first test slot and the second test slot.

80. The method of claim 79, wherein actuating the automated machinery to operate the clamping mechanism comprises clamping the storage device transporter to the first storage device prior to moving the storage device transporter between the first test slot and the second test slot.

81. The method of claim 79, wherein actuating the automated machinery to operate the clamping mechanism comprises clamping the storage device transporter to the first storage device as the storage device transporter is being moved between the first test slot and the second test slot.

82. The method of claim 79, wherein moving the storage device transporter between the first test slot and the second test slot comprises moving the storage device transporter carrying the first storage device from the first test slot towards the second test slot.

83. The method of claim 82, further comprising:
actuating the automated machinery to operate the clamping mechanism and thereby unclamping the storage device transporter from the first test slot; and then
actuating the automated machinery to remove the storage device transporter from the first test slot.

84. The method of claim 83, further comprising:
actuating the automated machinery to operate the clamping mechanism and thereby unclamping the storage device transporter from the first storage device prior to removing the storage device transporter from the first test slot.

85. The method of claim 83, further comprising:
actuating the automated machinery to operate the clamping mechanism and thereby unclamping the storage device transporter from the first storage device, and then
actuating the automated machinery to insert the storage device transporter and the first storage device into the second test slot.

86. The method of claim 85, further comprising actuating the automated machinery to operate the clamping mechanism and thereby clamping the storage device transporter to the second test slot after the storage device transporter and the first storage device are inserted into the second test slot.
